(19) United States
(12) Patent Application Publication
(10) Pub. No.: US 2025/0232956 A1
(43) Pub. Date: Jul. 17, 2025

(54) PLASMA PROCESSING DEVICE

(71) Applicant: Tokyo Electron Limited, Tokyo (JP)

(72) Inventors: Nozomu NAGASHIMA, Miyagi (JP); Daisuke YOSHIKOSHI, Miyagi (JP); Kunihiko YAMAGATA, Miyagi (JP); Satoru TERUUCHI, Miyagi (JP); Tomotaka SUKIGARA, Miyagi (JP)

(73) Assignee: Tokyo Electron Limited, Tokyo (JP)

(21) Appl. No.: 19/094,138

(22) Filed: Mar. 28, 2025

Related U.S. Application Data
(63) Continuation of application No. PCT/JP2023/034100, filed on Sep. 20, 2023.
(60) Provisional application No. 63/377,957, filed on Sep. 30, 2022.

(51) Int. Cl. H01J 37/32

(52) U.S. Cl. CPC H01J 37/32183; H01J 37/3211

(57) ABSTRACT

The present disclosure provides a plasma processing apparatus comprising: a plasma processing chamber; a substrate support; an electrode or an antenna; a radio frequency power supply; a power receiving coil electrically connected to the at least one power-consuming member; a power transmitting coil electromagnetically inductively coupled with the power receiving coil; a power transmitting unit electrically connected to the power transmitting coil to supply a power to the power transmitting coil; and a controller. The power transmitting unit includes a voltage detector and a current detector, and the controller is configured to determine a required power level corresponding to a parameter value including an input impedance obtained from the input voltage and the input current or a load resistance value of the at least one power-consuming member, and to control the power transmitting unit to output an output power having the required power level.

### CROSS-REFERENCE TO RELATED APPLICATIONS

This application is a bypass continuation application of International Application No. PCT/JP2023/034100 having an international filing date of Sep. 20, 2023 and designating the United States, the International Application being based upon and claiming the benefit of priority from U.S. Provisional Patent Application No. 63/377,957 filed on Sep. 30, 2022, the entire contents of each are incorporated herein by reference.

### TECHNICAL FIELD

An exemplary embodiment of the present disclosure relates to a plasma processing apparatus.

### BACKGROUND

A plasma processing apparatus is used for plasma processing. The plasma processing apparatus includes a chamber and a substrate support (placing table) disposed in the chamber. The substrate support has a base (lower electrode) and an electrostatic chuck for holding a substrate. A temperature control element (e.g., a heater) for controlling a temperature of a substrate is provided in the electrostatic chuck. In addition, a filter is provided between the temperature control element and a power supply for the temperature control element in order to attenuate or block a high-frequency noise that enters a line such as a power supply line and/or a signal line from a high-frequency electrode and/or another electrical member in the chamber. One type of such plasma processing apparatus is disclosed in Japanese Laid-open Patent Publication No. 2015-173027.

### SUMMARY

An exemplary embodiment of the present disclosure provides a technique for supplying power by electromagnetic inductive coupling according to a load resistance value of a power-consuming member in a plasma processing apparatus without passing through a power storage unit.

Specifically, the present disclosure provides a plasma processing apparatus comprising: a plasma processing chamber; a substrate support disposed in the plasma processing chamber; an electrode or an antenna disposed outside a plasma processing space in the plasma processing chamber, the electrode or the antenna being disposed such that a space in the plasma processing chamber is located between the electrode or antenna and the substrate support; a radio frequency (RF) power supply configured to generate an RF power, and electrically connected to the substrate support, the electrode or the antenna; at least one power-consuming member disposed in the plasma processing chamber or the substrate support; a power receiving coil that is electrically connected to said at least one power-consuming member; a power transmitting coil that is electromagnetically inductively coupled with the power receiving coil; a power transmitting unit that is electrically connected to the power transmitting coil to supply a power to the power transmitting coil; and a controller. The power transmitting unit includes a voltage detector configured to detect an input voltage to the power transmitting coil and a current detector configured to detect an input current to the power transmitting coil, and the controller is configured to determine a required power level corresponding to a parameter value including an input impedance obtained from the input voltage and the input current or a load resistance value of said at least one power-consuming member, and to control the power transmitting unit to output an output power having the required power level.

### BRIEF DESCRIPTION OF THE DRAWINGS

FIG. 1 is a diagram for explaining a configuration example of a plasma processing system.

FIG. 2 is a diagram for explaining a configuration example of a capacitively coupled plasma processing apparatus.

FIG. 3 is a diagram schematically illustrating a plasma processing apparatus according to one exemplary embodiment.

FIG. 4 is a diagram schematically illustrating a plasma processing apparatus according to another exemplary embodiment.

FIG. 5 is a diagram schematically illustrating a plasma processing apparatus according to still another exemplary embodiment.

FIG. 6 is a diagram schematically illustrating a plasma processing apparatus according to still another exemplary embodiment.

FIG. 7 is a diagram schematically illustrating a plasma processing apparatus according to still another exemplary embodiment.

FIG. 8 is a diagram showing a power transmitting unit according to one exemplary embodiment.

FIG. 9 is a diagram showing a power transmitting coil unit and a power receiving coil unit according to one exemplary embodiment.

FIG. 10 is a diagram showing a power transmitting coil unit and a power receiving coil unit according to one exemplary embodiment.

FIG. 11 is a diagram showing a power transmitting coil unit and a power receiving coil unit according to one exemplary embodiment.

FIG. 12 is a graph showing impedance characteristics of a power receiving coil unit according to one exemplary embodiment.

FIG. 13 is a diagram showing a high-frequency filter according to one exemplary embodiment.

FIG. 14 is a diagram showing a rectifying and smoothing unit according to one exemplary embodiment.

FIG. 15 is a diagram showing an RF filter according to one exemplary embodiment.

FIG. 16 is a diagram showing a communication part of a power transmitting unit and a communication part of a rectifying and smoothing unit according to one exemplary embodiment.

FIG. 17 is a diagram schematically showing a plasma processing apparatus according to still another exemplary embodiment.

FIG. 18 is a diagram schematically showing a plasma processing apparatus according to still another exemplary embodiment.

FIG. 19 is a diagram showing a communication part of a power transmitting unit and a communication part of a rectifying and smoothing unit according to another exemplary embodiment.

FIG. 20 is a diagram schematically showing a plasma processing apparatus according to still another exemplary embodiment.

FIG. 21 is a diagram schematically showing a plasma processing apparatus according to still another exemplary embodiment.

FIG. 22 is a diagram schematically showing a plasma processing apparatus according to still another exemplary embodiment.

FIGS. 23A and 23B are diagrams showing a power storage unit according to one exemplary embodiment.

FIG. 24 is a diagram showing a voltage control converter according to one exemplary embodiment.

FIG. 25 is a diagram showing a constant voltage controller according to one exemplary embodiment.

FIG. 26 is a diagram showing a constant voltage controller according to another exemplary embodiment.

FIG. 27 is a diagram schematically showing a plasma processing apparatus according to still another exemplary embodiment.

FIG. 28 is a diagram showing an exemplary equivalent circuit of a power transmitting coil unit and a power receiving coil unit.

FIG. 29 is a diagram showing an example of at least one table.

FIG. 30 is a diagram showing an example of at least one table.

FIG. 31 is a diagram schematically showing a plasma processing apparatus according to still another exemplary embodiment.

FIG. 32 is an exemplary timing chart showing a load resistance value, an input impedance, a transmission power, and a state of a switching element.

FIG. 33 is a flowchart of a power supply method according to one exemplary embodiment.

FIG. 34 is a flowchart of a power supply method according to one exemplary embodiment.

FIG. 35 is a diagram schematically showing a plasma processing apparatus according to still another exemplary embodiment.

FIG. 36 is a diagram schematically showing a plasma processing apparatus according to still another exemplary embodiment.

FIG. 37 is a diagram schematically showing a plasma processing apparatus according to still another exemplary embodiment.

FIG. 38 is a diagram schematically showing a plasma processing apparatus according to still another exemplary embodiment.

FIG. 39 is a diagram showing a power transmitting coil unit and a power receiving coil unit in a plasma processing apparatus according to still another exemplary embodiment.

FIG. 40 is a diagram showing a power transmitting coil unit and a power receiving coil unit in a plasma processing apparatus according to still another exemplary embodiment.

FIG. 41 is a diagram schematically showing a plasma processing apparatus according to still another exemplary embodiment.

FIG. 42 is a diagram schematically showing a plasma processing apparatus according to still another exemplary embodiment.

FIG. 43 is a diagram showing an immittance converter in a plasma processing apparatus according to still another exemplary embodiment.

FIG. 44 is a diagram showing a power transmitting unit that can be employed in plasma processing apparatuses according to various exemplary embodiments.

FIG. 45 is a diagram explaining adjustment of a duty of a transmission voltage of a power transmitting unit that can be employed in plasma processing apparatuses according to various exemplary embodiments.

FIG. 46 is a diagram showing a power transmitting unit and an AC/DC converter that can be employed in plasma processing apparatuses according to various exemplary embodiments.

FIG. 47 is a diagram showing a power receiving coil unit that can be employed in plasma processing apparatuses according to various exemplary embodiments.

FIG. 48 is a diagram showing a configuration of a power receiving coil and a power transmitting coil that can be employed in plasma processing apparatuses according to various exemplary embodiments.

FIG. 49 is a diagram showing a configuration of a power receiving coil and a power transmitting coil that can be employed in plasma processing apparatuses according to various exemplary embodiments.

FIG. 50 is a diagram showing a configuration of a power receiving coil unit and a rectifying and smoothing unit that can be employed in plasma processing apparatuses according to various exemplary embodiments.

FIG. 51 is a diagram showing a configuration of a power receiving coil unit and a rectifying and smoothing unit that can be employed in plasma processing apparatuses according to various exemplary embodiments.

FIG. 52 is a diagram showing an integrated configuration related to power supply that can be employed in a plasma processing apparatus according to various exemplary embodiments.

FIG. 53 is a diagram showing an integrated configuration related to power supply that can be employed in plasma processing apparatuses according to various exemplary embodiments.

FIG. 54 is a diagram showing an integrated configuration related to power supply that can be employed in plasma processing apparatuses according to various exemplary embodiments.

FIG. 55 is a diagram showing an integrated configuration related to power supply that can be employed in plasma processing apparatuses according to various exemplary embodiments.

FIG. 56 is a diagram showing an integrated configuration related to power supply that can be employed in plasma processing apparatuses according to various exemplary embodiments.

FIG. 57 is a diagram showing an integrated configuration related to power supply that can be employed in plasma processing apparatuses according to various exemplary embodiments.

FIG. 58 is a diagram showing an integrated configuration related to power supply that can be employed in plasma processing apparatuses according to various exemplary embodiments.

FIG. 59 is a diagram showing an integrated configuration related to power supply that can be employed in plasma processing apparatuses according to various exemplary embodiments.

FIG. 60 is a diagram showing an integrated configuration related to power supply that can be employed in plasma processing apparatuses according to various exemplary embodiments.

FIG. 61 is a diagram showing an integrated configuration related to power supply that can be employed in plasma processing apparatuses according to various exemplary embodiments.

FIG. 62 is a diagram showing an integrated configuration related to power supply that can be employed in plasma processing apparatuses according to various exemplary embodiments.

FIG. 63 is a diagram showing an integrated configuration related to power supply that can be employed in plasma processing apparatuses according to various exemplary embodiments.

FIG. 64 is a diagram showing an integrated configuration related to power supply that can be employed in plasma processing apparatuses according to various exemplary embodiments.

FIG. 65 is a diagram showing an integrated configuration related to power supply that can be employed in plasma processing apparatuses according to various exemplary embodiments.

### DETAILED DESCRIPTION

Hereinafter, various exemplary embodiments will be described in detail with reference to the accompanying drawings. Like reference numerals will be used for like or corresponding parts throughout the drawings.

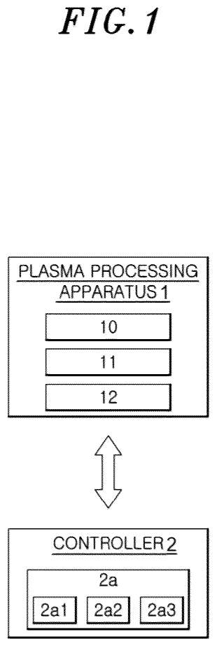

FIG. 1 is a diagram for explaining a configuration example of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 has at least one gas supply port for supplying at least one processing gas to the plasma processing space, and at least one gas exhaust port for exhausting a gas from the plasma processing space. The gas supply port is connected to a gas supply part 20 to be described later, and the gas exhaust port is connected to an exhaust system 40 to be described later. The substrate support 11 is disposed in the plasma processing space, and has a substrate supporting surface for supporting a substrate.

The plasma generator 12 is configured to generate plasma from at least one processing gas supplied into the plasma processing space. The plasma generated in the plasma processing space may be capacitively coupled plasma (CCP), inductively coupled plasma (ICP), electron-cyclotron-resonance plasma (ECR plasma), helicon wave plasma (HWP), surface wave plasma (SWP), or the like. Further, various types of plasma generators including an alternating current (AC) plasma generator and a direct current (DC) plasma generator may be used. In one embodiment, an AC signal (AC power) used in the AC plasma generator has a frequency within a range of 100 kHz to 10 GHz. Thus, the AC signal includes a radio frequency (RF) signal and a microwave signal. In one embodiment, the RF signal has a frequency within a range of 100 kHz to 150 MHz.

The controller 2 processes computer-executable instructions that cause the plasma processing apparatus 1 to execute various steps described in the present disclosure. The controller 2 may be configured to control individual components of the plasma processing apparatus 1 to execute various steps described herein. In one embodiment, the controller 2 may be partially or entirely included in the plasma processing apparatus 1. The controller 2 may include a processing part 2a1, a storage part 2a2, and a communication interface 2a3. The controller 2 is realized, e.g., by a computer 2a. The processing part 2a1 may be configured to perform various control operations by reading a program from the storage part 2a2 and executing the read program. The program may be stored in the storage part 2a2 in advance, or may be acquired via a medium when necessary. The acquired program is stored in the storage part 2a2, and is read from the storage part 2a2 and executed by the processing part 2a1. The medium may be various storage media that are readable by the computer 2a, or may be a communication line connected to the communication interface 2a3. The processing part 2a1 may be a central processing unit (CPU). The storage part 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

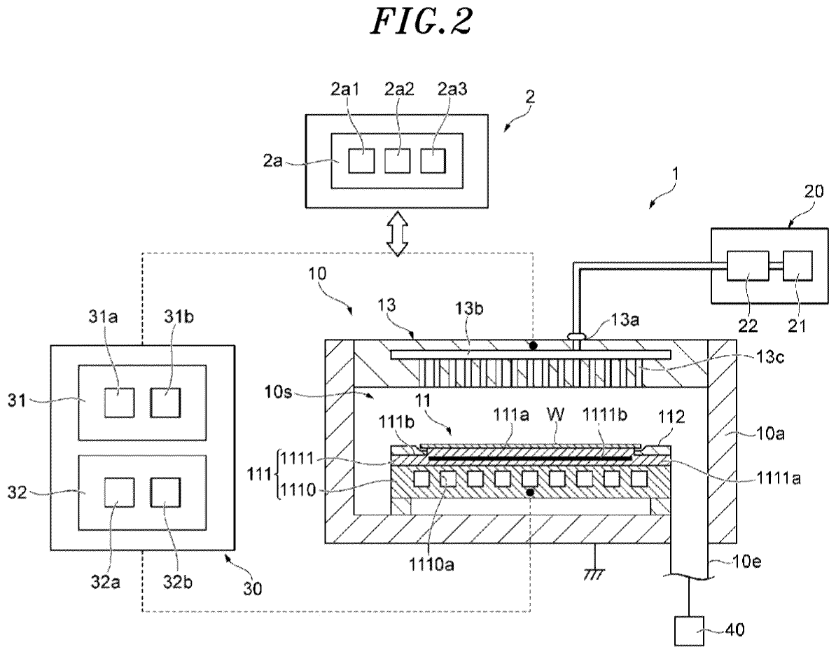

Hereinafter, a configuration example of a capacitively coupled plasma processing apparatus will be described as an example of the plasma processing apparatus 1. FIG. 2 is a diagram for explaining a configuration example of a capacitively coupled plasma processing apparatus.

The capacitively coupled plasma processing apparatus 1 includes the plasma processing chamber 10, the gas supply part 20, the power supply part 30, and the exhaust system 40. The plasma processing apparatus 1 further includes the substrate support 11 and a gas introducing part. The gas introducing part is configured to introduce at least one processing gas into the plasma processing chamber 10. The gas introducing part includes a shower head 13. The substrate support 11 is disposed in the plasma processing chamber 10. The shower head 13 is disposed above the substrate support 11. In one embodiment, the shower head 13 constitutes at least a part of the ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from the housing of the plasma processing chamber 10.

The substrate support 11 includes a main body 111 and a ring assembly 112. The main body 111 has a central region 111a for supporting a substrate W, and an annular region 111b for supporting the ring assembly 112. A wafer is an example of a substrate W. The annular region 111b of the main body 111 surrounds the central region 111a of the main body 111 in plan view. The substrate W is disposed on the central region 111a of the main body 111, and the ring assembly 112 is disposed on the annular region 111b of the main body 111 to surround the substrate W on the central region 111a of the main body 111. Therefore, the central region 111a is also referred to as a substrate supporting surface for supporting the substrate W, and the annular region 111b is also referred to as a ring supporting surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode (also referred to as an attraction electrode, a chuck electrode, or a clamp electrode) 1111b disposed in the ceramic member 1111a. The ceramic member 1111a has a central region 111a. In one embodiment, the ceramic member 1111a also has an annular region 111b. Further, another member surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode connected to an RF power supply 31 and/or a DC power supply 32 to be described later may be disposed in the ceramic member 1111a. In this case, at least one RF/DC electrode functions as a lower electrode. When a bias RF signal and/or a DC signal to be described later is supplied to at least one RF/DC electrode, the RF/DC electrode is also referred to as a bias electrode. Further, the conductive member of the base 1110 and at least one RF/DC electrode may function as a plurality of lower electrodes. Further, the electrostatic electrode 1111b may function as a lower electrode. Thus, the substrate support 11 includes at least one lower electrode.

The ring assembly 112 includes one or multiple annular members. In one embodiment, one or multiple annular members include one or multiple edge rings and at least one cover ring. The edge ring is made of a conductive or insulating material, and the cover ring is made of an insulating material.

Further, the substrate support 11 may include a temperature control module configured to control at least one of the electrostatic chuck 1111, the ring assembly 112, and the substrate to a target temperature. The temperature control module may include a heater, a heat transfer medium, a channel 1110a, or a combination thereof. A heat transfer fluid such as brine or a gas flows through the channel 1110a. In one embodiment, the channel 1110a is formed in the base 1110, and one or multiple heaters are disposed in the ceramic member 1111a of the electrostatic chuck 1111. Further, the substrate support 11 may include a heat transfer gas supply configured to supply a heat transfer gas to a gap between the backside of the substrate W and the central region 111a.

The shower head 13 is configured to introduce at least one processing gas from the gas supply part 20 into the plasma processing space 10s. The shower head 13 has at least one gas supply port 13a, at least one gas diffusion space 13b, and a plurality of gas inlet ports 13c. The processing gas supplied to the gas supply port 13a passes through the gas diffusion space 13b and is introduced into the plasma processing space 10s from the plurality of gas inlet ports 13c. Further, the shower head 13 includes at least one upper electrode. In addition to the shower head 13, the gas introducing part may include, one or multiple side gas injectors (SGI) attached to one or multiple openings formed in the sidewall 10a.

The gas supply part 20 may include at least one gas source 21 and at least one flow rate controller 22. In one embodiment, the gas supply part 20 is configured to supply at least one processing gas from the corresponding gas source 21 to the shower head 13 via the corresponding flow rate controller 22. The flow rate controllers 22 may include, for example, a mass flow controller or a pressure-controlled flow rate controller. Further, the gas supply part 20 may include at least one flow modulation device for modulating a flow rate of at least one processing gas or causing it to pulsate.

The power supply part 30 includes an RF power supply 31 connected to the plasma processing chamber 10 via at least one impedance matching circuit. The RF power supply 31 is configured to supply at least one RF signal (RF power) to at least one lower electrode and/or at least one upper electrode. Accordingly, plasma is generated from at least one processing gas supplied to the plasma processing space 10s. Hence, the RF power supply 31 can function as at least a part of the plasma generator 12. In addition, by supplying a bias RF signal to at least one lower electrode, a bias potential is generated at the substrate W, and ion components in the generated plasma can be attracted to the substrate W.

In one embodiment, the RF power supply 31 includes a first RF generator 31a and a second RF generator 31b. The first RF generator 31a is connected to at least one lower electrode and/or at least one upper electrode via at least one impedance matching circuit, and is configured to generate a source RF signal (source RF power) for plasma generation. In one embodiment, the source RF signal has a frequency within a range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is connected to at least one lower electrode via at least one impedance matching circuit, and is configured to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency within a range of 100 kHz to 60 MHz. In one embodiment, the second RF generator 31b may be configured to generate a plurality of bias RF signals having different frequencies. The generated one or multiple bias RF signals are provided to at least one lower electrode. Further, in various embodiments, at least one of the source RF signal and the bias RF signal may pulsate.

Further, the power supply part 30 may include a DC power supply 32 connected to the plasma processing chamber 10. The DC power supply 32 includes a first DC generator 32a and a second DC generator 32b. In one embodiment, the first DC generator 32a is connected to at least one lower electrode, and is configured to generate a first DC signal. The generated first DC signal is applied to at least one lower electrode. In one embodiment, the second DC generator 32b is connected to at least one upper electrode, and is configured to generate a second DC signal. The generated second DC signal is applied to at least one upper electrode.

In various embodiments, the first and second DC signals may pulsate. In this case, a sequence of voltage pulses is applied to at least one lower electrode and/or at least one upper electrode. The voltage pulse may have a rectangular pulse waveform, a trapezoidal pulse waveform, a triangular pulse waveform, or a combination thereof. In one embodiment, a waveform generator for generating a sequence of voltage pulses from the DC signal is connected between the first DC generator 32a and at least one lower electrode. Thus, the first DC generator 32a and the waveform generator constitute a voltage pulse generator. When the second DC generator 32b and the waveform generator constitute a voltage pulse generator, the voltage pulse generator is connected to at least one upper electrode. The voltage pulse may have positive polarity or negative polarity. Further, the sequence of voltage pulses may include one or multiple positive polarity voltage pulses and one or multiple negative polarity voltage pulses in one cycle. Further, the first and second DC generator 32a and 32b may be provided in addition to the RF power supply 31, or the first DC generator 32a may be provided instead of the second RF generator 31b.

The exhaust system 40 may be connected to, for example, a gas exhaust port 10e provided at the bottom portion of the plasma processing chamber 10. The exhaust system 40 may include a pressure control valve and a vacuum pump. The pressure in the plasma processing space 10s is adjusted by the pressure control valve. The vacuum pump may include a turbomolecular pump, a dry pump, or a combination thereof.

Further, in the capacitively coupled plasma processing apparatus 1, the upper electrode is disposed such that the plasma processing space is located between the upper electrode and the substrate support 11. A radio frequency (RF) power supply such as the first RF generator 31a is electrically connected to the upper electrode or the lower electrode in the substrate support 11. When the plasma processing apparatus 1 is an inductively coupled plasma processing apparatus, an antenna is disposed such that the plasma processing space is located between the antenna and the substrate support 11. The RF power supply such as the first RF generator 31a is electrically connected to the antenna. When the plasma processing apparatus 1 is a plasma processing apparatus that generates plasma by surface waves such as microwaves, an antenna is disposed such that the plasma processing space is located between the antenna and the substrate support 11. The RF power supply such as the first RF Generator 31a is electrically connected to the antenna via a waveguide.

Hereinafter, plasma processing apparatuses according to various exemplary embodiments will be described. The respective plasma processing apparatuses to be described below are configured to supply a power to at least one power-consuming member in the plasma processing chamber 10 by wireless power supply (electromagnetic inductive coupling), and may have the same configuration as that of the plasma processing apparatus 1.

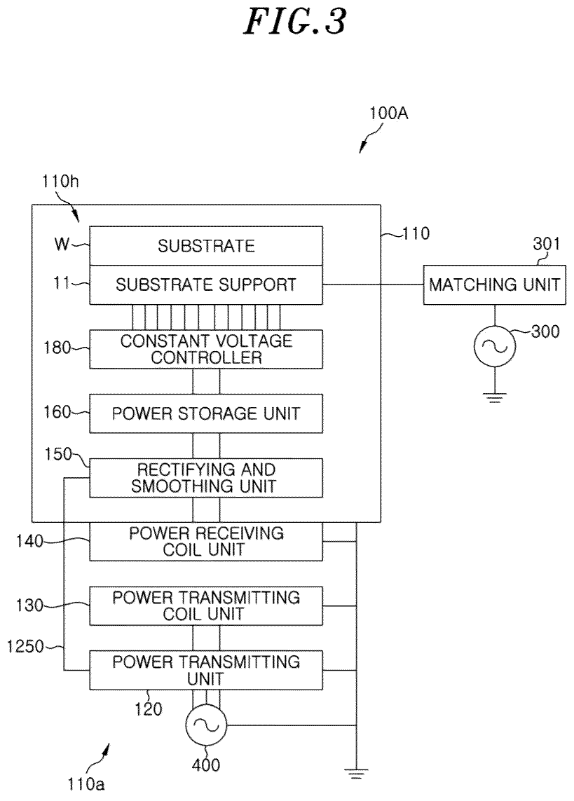

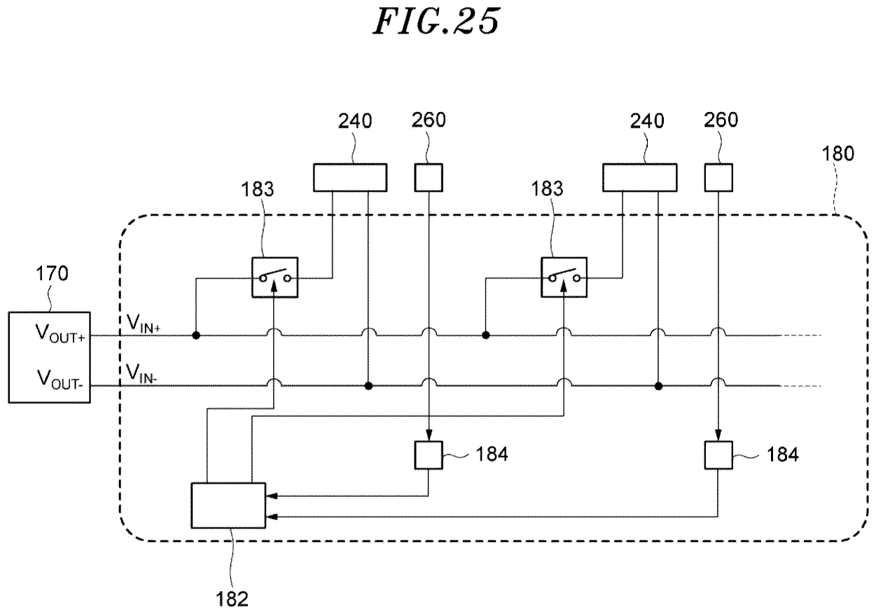

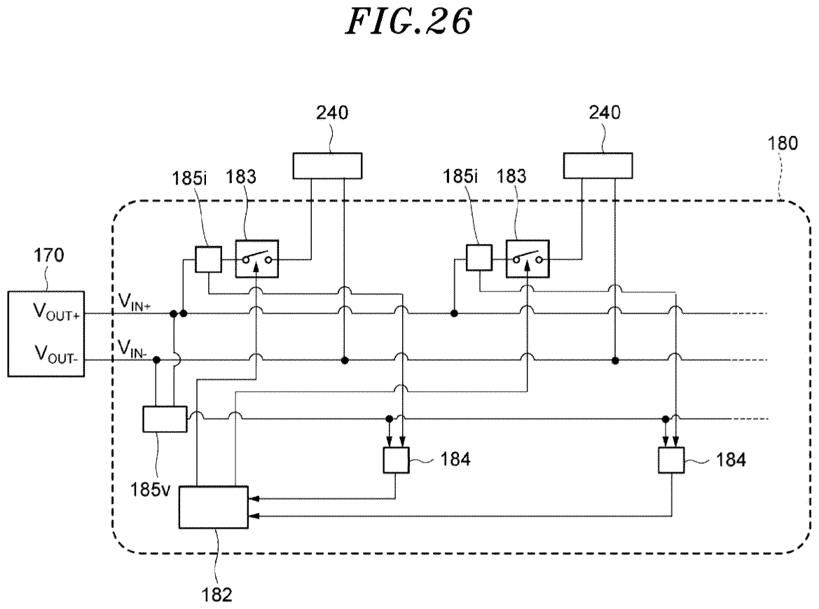

FIG. 3 is a schematic diagram of a plasma processing apparatus according to one exemplary embodiment. A plasma processing apparatus 100A shown in FIG. 3 includes at least one RF power supply part 300, a power receiving coil unit 140, a power storage unit 160, and at least one power-consuming member 240 (see FIGS. 25 and 26). The plasma processing apparatus 100A may further include a power transmitting unit 120, a power transmitting coil unit 130, a rectifying and smoothing unit 150, a constant voltage controller 180 (an example of a voltage controller), a ground frame 110, and a matching unit 301.

At least one RF power supply part 300 includes the first RF generator 31a and/or the second RF generator 31b. At least one RF power supply part 300 is electrically connected to the substrate support 11 via a matching unit 301. The matching unit 301 includes at least one impedance matching circuit.

The ground frame 110 includes the plasma processing chamber 10 and is electrically grounded. The ground frame 110 electrically isolates an internal space 110h (RF-Hot space) from an external space 110a (atmospheric space). The ground frame 110 surrounds the substrate support 11 disposed in the space 110h. Further, in the plasma processing apparatus 100A, the rectifying and smoothing unit 150, the power storage unit 160, and the constant voltage controller 180 are disposed in the space 110h. Further, in the plasma processing apparatus 100A, the power transmitting unit 120, the power transmitting coil unit 130, and the power receiving coil unit 140 are disposed in the space 110a. Further, the space 110h includes a depressurized space (vacuum space) and a non-depressurized space (non-vacuum space). The depressurized space is the space in the plasma processing chamber 10, and the non-depressurized space is the space outside the plasma processing chamber 10. The substrate support 11 and the substrate W are disposed in the depressurized space. The rectifying and smoothing unit 150, the power storage unit 160, and the constant voltage controller 180 are disposed in the non-depressurized space.

The devices located in the space 110a, such as the power transmission part 120, the power transmitting coil unit 130, and the power receiving coil unit 140, are covered with a metal housing made of a metal such as aluminum or the like, and the metal housing is grounded. Accordingly, the leakage of RF noise caused by the RF power such as the first RF signal (source RF signal) and/or the second RF signal (bias RF signal) is suppressed. An insulation distance exists between the metal housing and each power supply line. Further, in the following description, the RF power such as the first RF signal and/or the second RF signal that propagates toward the power transmission part 120 may be referred to as RF noise, common mode noise, or conductive noise.

The power transmitting unit 120 is electrically connected between an AC power supply 400 (e.g., a commercial AC power supply) and the power transmitting coil unit 130. The power transmitting unit 120 receives the frequency of the AC power from the AC power supply 400 and converts the frequency of the AC power to a transmission frequency, thereby generating the AC power having the transmission frequency, i.e., the transmission AC power.

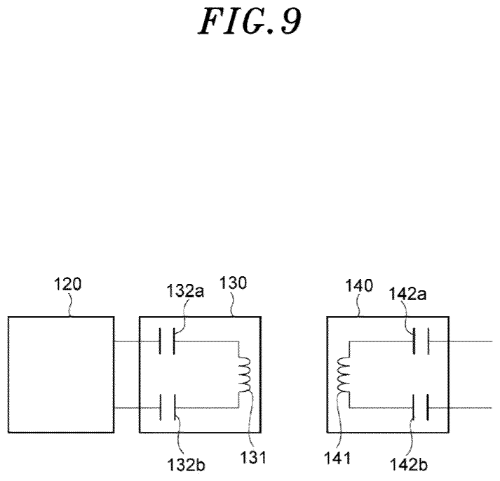

The power transmitting coil unit 130 includes a power transmitting coil 131 (see FIG. 9) to be described later. The power transmitting coil 131 is electrically connected to the power transmitting unit 120. The power transmitting coil 131 receives the transmission AC power from the power transmitting unit 120 and wirelessly transmits the transmission AC power to the power receiving coil 141.

The power receiving coil unit 140 includes a power receiving coil 141 (see FIG. 9) to be described later. The power receiving coil 141 is electromagnetically inductively coupled to the power transmitting coil 131. The electromagnetic inductive coupling includes magnetic field coupling and electric field coupling. Further, the magnetic field coupling includes magnetic field resonance (also referred to as magnetic resonance). The distance between the power receiving coil 141 and the power transmitting coil 131 is set to suppress common mode noise (conductive noise). Further, the distance between the power receiving coil 141 and the power transmitting coil 131 is set to a distance that allows a power to be supplied. The distance between the power receiving coil 141 and the power transmitting coil 131 is set such that the attenuation amount of the RF power (i.e., RF noise) between the power receiving coil 141 and the power transmitting coil 131 becomes less than or equal to a threshold, and the power from the power transmitting coil 131 can be received by the power receiving coil 141. The threshold for the attenuation amount is set to a value that allows damages or malfunction of the power transmitting unit 120 to be sufficiently prevented. The threshold for the attenuation amount is, for example, −20 dB. The transmission AC power received by the power receiving coil unit 140 is outputted to the rectifying and smoothing unit 150.

The rectifying and smoothing unit 150 is electrically connected between the power receiving coil unit 140 and the power storage unit 160. The rectifying and smoothing unit 150 generates a DC power by full-wave rectification and smoothing of the transmission AC power from the power receiving coil unit 140. The DC power generated by the rectifying and smoothing unit 150 is stored in the power storage unit 160. The power storage unit 160 is electrically connected between the rectifying and smoothing unit 150 and the constant voltage controller 180. Further, the rectifying and smoothing unit 150 may generate a DC power by half-wave rectification and smoothing of the transmission AC power from the power receiving coil unit 140.

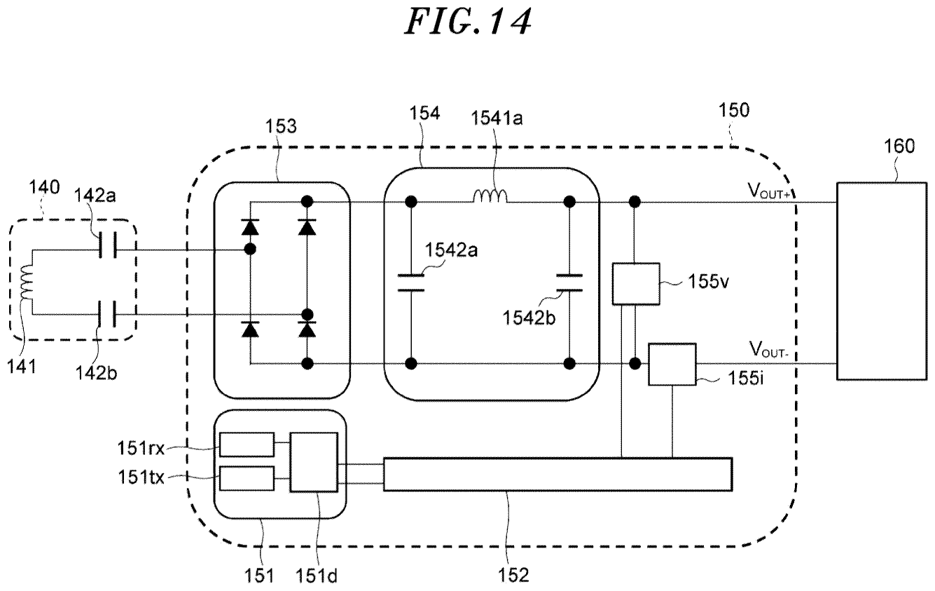

The rectifying and smoothing unit 150 and the power transmitting unit 120 are electrically connected to each other by a signal line 1250. The rectifying and smoothing unit 150 transmits an instruction signal to the power transmitting unit 120 through the signal line 1250. The instruction signal is a signal for instructing the power transmitting unit 120 to start or stop supply of the transmission AC power. The instruction signal may include a status signal, an abnormality detection signal, and a cooling control signal for the power transmitting coil unit 130 and the power receiving coil unit 140. The status signal is a value of a voltage, a current, a magnitude and/or a phase of the power detected by a voltage detector 155v (see FIG. 14) and a current detector 155i (see FIG. 14) of the rectifying and smoothing unit 150. The abnormality detection signal is a signal for transmitting the occurrence of failure and/or temperature abnormality of the rectifying and smoothing unit 150 to the power transmitting unit 120. The cooling control signal controls cooling mechanisms provided in the power transmitting coil unit 130 and the power receiving coil unit 140. The cooling control signal controls the number of rotations of a fan in the case of air cooling, or the flow rate and/or temperature of a coolant in the case of liquid cooling, for example.

The constant voltage controller 180 applies a voltage to at least the power-consuming member 240 using the power stored in the power storage unit 160. The constant voltage controller 180 can control start and stop of the application of a voltage to at least the power-consuming member 240.

In the plasma processing apparatus 100A, the power receiving coil 141 functions as a filter for RF noise caused by the RF power such as the first RF signal and/or the second RF signal, thereby suppressing the propagation of the RF noise to a power supply outside the plasma processing apparatus.

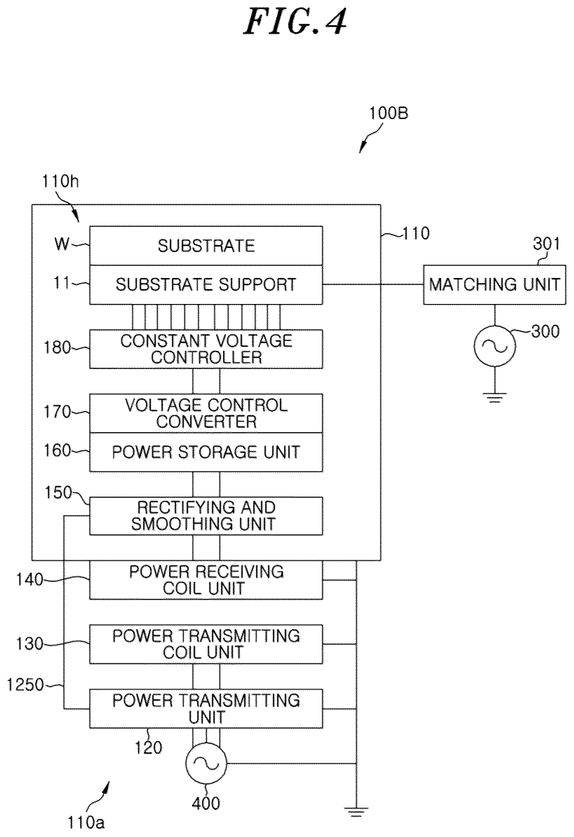

Hereinafter, FIG. 4 will be referred to. FIG. 4 is a diagram schematically showing a plasma processing apparatus according to another exemplary embodiment. Hereinafter, the differences between a plasma processing apparatus 100B shown in FIG. 4 and the plasma processing apparatus 100A will be described.

The plasma processing apparatus 100B further includes a voltage control converter 170. The voltage control converter 170 is a DC-DC converter, and is connected between the power storage unit 160 and the constant voltage controller 180. The voltage control converter 170 can be configured to input a constant output voltage to the constant voltage controller 180 even when voltage fluctuation occurs in the power storage unit 160. Further, the voltage fluctuation in the power storage unit 160 may occur as voltage decrease due to the storage power in the case where the power storage unit 160 is configured as an electric double layer, for example.

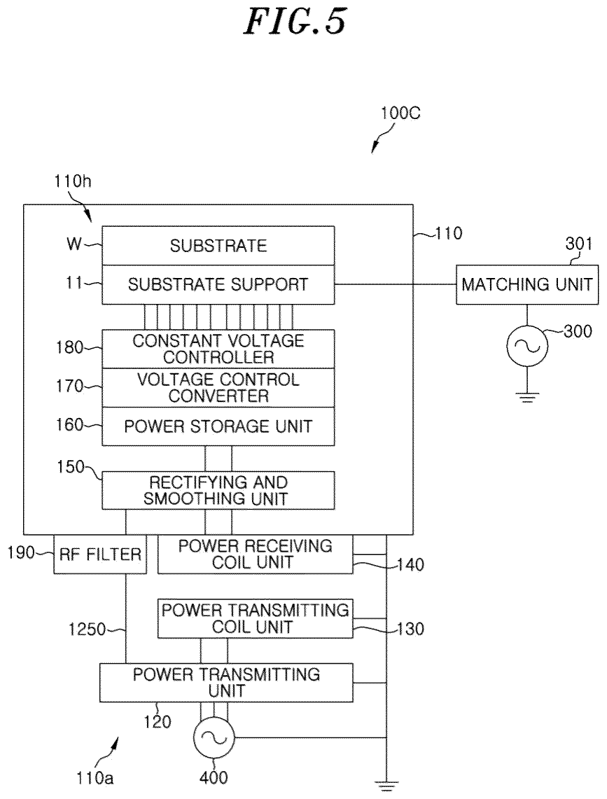

Hereinafter, FIG. 5 will be referred to. FIG. 5 is a diagram schematically showing a plasma processing apparatus according to still another exemplary embodiment. Hereinafter, the differences between a plasma processing apparatus 1000 shown in FIG. 5 and the plasma processing apparatus 100B will be described.

The plasma processing apparatus 1000 further includes an RF filter 190. The RF filter 190 is connected between the rectifying and smoothing unit 150 and the power transmitting unit 120. The RF filter 190 constitutes a part of the signal line 1250. The RF filter 190 has characteristics of suppressing the propagation of the RF power (RF noise) through the signal line 1250. In other words, the RF filter 190 includes a low-pass filter that has a high impedance for the RF noise (conductive noise) but allows an instruction signal of a relatively low frequency to pass therethrough.

In the plasma processing apparatus 1000, the power storage unit 160, the voltage control converter 170, and the constant voltage controller 180 are integrated with each other. In other words, the power storage unit 160, the voltage control converter 170, and the constant voltage controller 180 are disposed in a single metal housing or formed on a single circuit board. Accordingly, the length of each of the pair of power supply lines (positive line and negative line) that connect the power storage unit 160 and the voltage control converter 170 to each other is shortened. In addition, it is possible to equalize the lengths of the pair of power supply lines connecting the power storage unit 160 and the voltage control converter 170. Further, the length of each of the pair of power supply lines (positive line and negative line) that connect the voltage control converter 170 and the constant voltage controller 180 to each other is shortened. In addition, the lengths of the pair of power supply lines that connect the voltage control converter 170 and the constant voltage controller 180 can be made equal. Therefore, malfunction and damage of the device caused by normal mode noise (voltage difference between the positive line and the negative line) are suppressed. Further, when another metal body that shields the electromagnetic field is provided in the plasma processing chamber 10 to surround the housing, the single housing does not necessarily have to be made of metal.

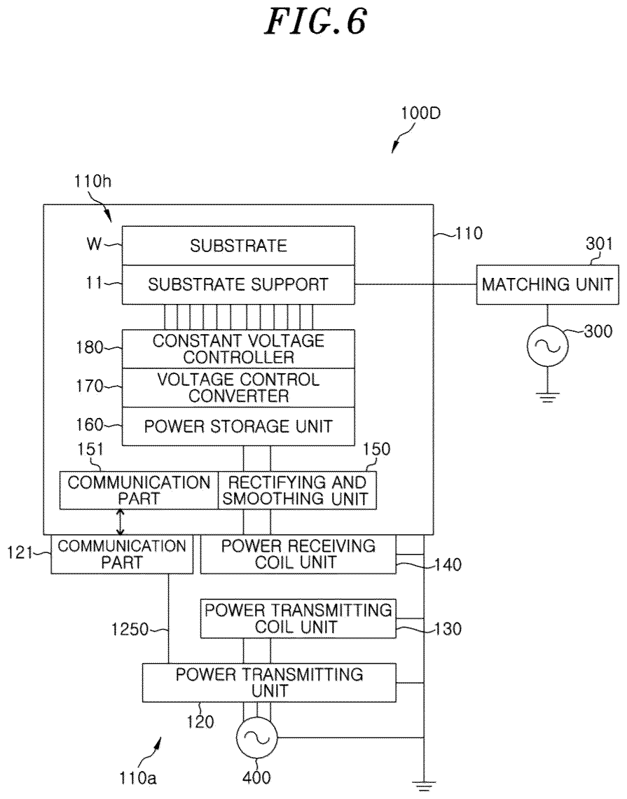

Hereinafter, FIG. 6 will be referred to. FIG. 6 is a diagram schematically showing a plasma processing apparatus according to still another exemplary embodiment. Hereinafter, the differences between a plasma processing apparatus 100D shown in FIG. 6 and the plasma processing apparatus 1000 will be described.

The plasma processing apparatus 100D does not include the RF filter 190. In the plasma processing apparatus 100D, the rectifying and smoothing unit 150 includes a communication part 151 that is a wireless part. The communication part 151 is disposed in a non-depressurized space. Further, the power transmitting unit 120 further includes a communication part 121 that is a wireless part. The communication part 121 is disposed in the space 110a. The above-described instruction signal is transmitted between the rectifying and smoothing unit 150 and the power transmitting unit 120 using the communication part 151 and the communication part 121. The communication part 121 and the communication part 151 will be described in detail later.

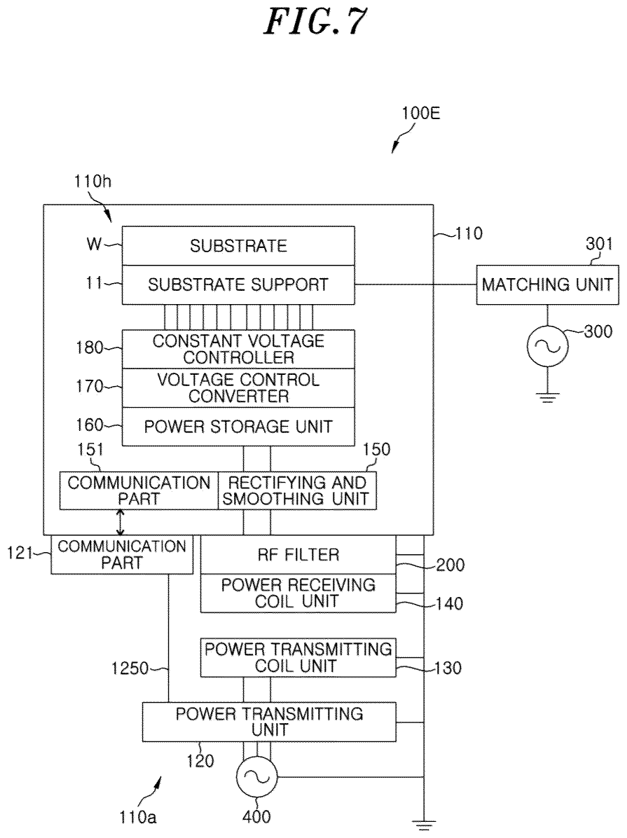

Hereinafter, FIG. 7 will be referred to. FIG. 7 is a diagram schematically showing a plasma processing apparatus according to still another exemplary embodiment. Hereinafter, the differences between a plasma processing apparatus 100E shown in FIG. 7 and the plasma processing apparatus 100D will be described.

The plasma processing apparatus 100E further includes an RF filter 200. The RF filter 200 is connected between the power receiving coil unit 140 and the rectifying and smoothing unit 150. The RF filter 200 has characteristics of reducing or blocking RF noise propagating from the power receiving coil unit 140 to the power transmitting coil 131 and the power transmitting unit 120. The RF filter 200 will be described in detail later.

Hereinafter, configurations of various parts for wireless power supply in the plasma processing apparatuses according to various exemplary embodiments will be described in detail.

### (Configuration of Power Transmitting Unit)

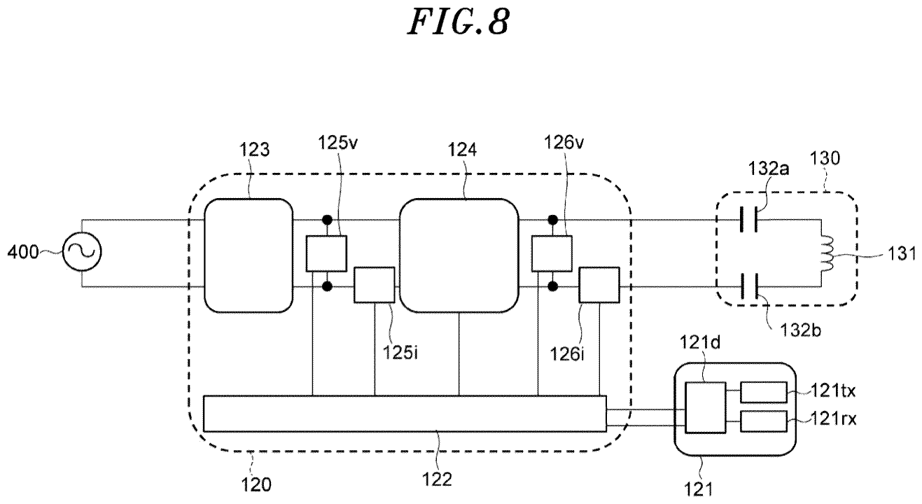

FIG. 8 is a diagram illustrating a power transmitting unit according to one exemplary embodiment. As described above, the power transmitting unit 120 receives the frequency of the AC power from the AC power supply 400 and converts the frequency of the AC power into a transmission frequency, thereby generating the transmission AC power having the transmission frequency.

In one embodiment, the power transmitting unit 120 includes a controller 122, a rectifying and smoothing unit 123, and an inverter 124. The controller 122 is configured as a processor such as a CPU or a programmable logic device such as a field-programmable gate array (FPGA).

The rectifying and smoothing unit 123 includes a rectifying circuit and a smoothing circuit. The rectifying circuit includes, for example, a diode bridge. The smoothing circuit includes, for example, a line capacitor. The rectifying and smoothing unit 123 generates a DC power by full-wave rectification and smoothing of the AC power from the AC power supply 400. Further, the rectifying and smoothing unit 123 may generate a DC power by half-wave rectification and smoothing of the AC power from the AC power supply 400.

The inverter 124 generates the transmission AC power having the transmission frequency from the DC power outputted by the rectifying and smoothing unit 123. The inverter 124 is, for example, a full-bridge inverter, and includes a plurality of triacs or a plurality of switching elements (for example, field effect transistors (FETs)). The inverter 124 generates the transmission AC power by ON/OFF control of the plurality of triacs or the plurality of switching elements by the controller 122. The transmission AC power outputted from the inverter 124 is outputted to the power transmitting coil unit 130.

The power transmitting unit 120 may further include a voltage detector 125v, a current detector 125i, a voltage detector 126v, and a current detector 126i. The voltage detector 125v detects a voltage value between a pair of power supply lines that connect the rectifying and smoothing unit 123 and the inverter 124. The current detector 125i detects a current value between the rectifying and smoothing unit 123 and the inverter 124. The voltage detector 126v detects a voltage value between a pair of power supply lines that connect the inverter 124 and the power transmitting coil unit 130. The current detector 126i detects a current value between the inverter 124 and the power transmitting coil unit 130. The voltage value detected by the voltage detector 125v, the current value detected by the current detector 125i, the voltage value detected by the voltage detector 126v, and the current value detected by the current detector 126i are notified to the controller 122.

The power transmitting unit 120 includes the communication part 121 described above. The communication part 121 includes a driver 121d, a transmitter 121tx, and a receiver 121 rx. The transmitter 121tx is a transmitter of a wireless signal or a transmitter of an optical signal. The receiver 121rx is a receiver of a wireless signal or a receiver of an optical signal. In the communication part 121, the transmitter 121tx is driven by the driver 121d to output a signal from the controller 122, as a wireless signal or an optical signal, from the transmitter 121tx. The signal outputted from the transmitter 121tx is received by the communication part 151 (see FIG. 14) to be described later. In addition, in the communication part 121, the receiver 121rx receives a signal such as the above-described instruction signal from the communication part 151, and the received signal is inputted to the controller 122 via the driver 121d. The controller 122 controls the inverter 124 in accordance with the instruction signal received from the communication part 151 via the communication part 121, the voltage value detected by the voltage detector 125v, the current value detected by the current detector 125i, the voltage value detected by the voltage detector 126v, and the current value detected by the current detector 126i, thereby switching start and stop of outputting the transmission AC power.

### (Power Transmitting Coil Unit and Power Receiving Coil Unit)

Hereinafter, FIGS. 9 to 11 will be referred to. FIGS. 9 to 11 are diagrams showing a power transmitting coil unit and a power receiving coil unit according to one exemplary embodiment. As shown in FIG. 9, the power transmitting coil unit 130 may include a resonant capacitor 132a and a resonant capacitor 132b, in addition to the power transmitting coil 131. The resonant capacitor 132a is connected between one of a pair of power supply lines that connect the power transmitting unit 120 and the power transmitting coil unit 130 to each other and one end of the power transmitting coil 131. The resonant capacitor 132b is connected between the other of the pair of power supply lines and the other end of the power transmitting coil 131. The power transmitting coil 131, the resonant capacitor 132a, and the resonant capacitor 132b constitute a resonant circuit for the transmission frequency. In other words, the power transmitting coil 131, the resonant capacitor 132a, and the resonant capacitor 132b have a resonant frequency that is substantially the same as the transmission frequency. Further, the power transmitting coil unit 130 may not include any one of the resonant capacitor 132a and the resonant capacitor 132b.

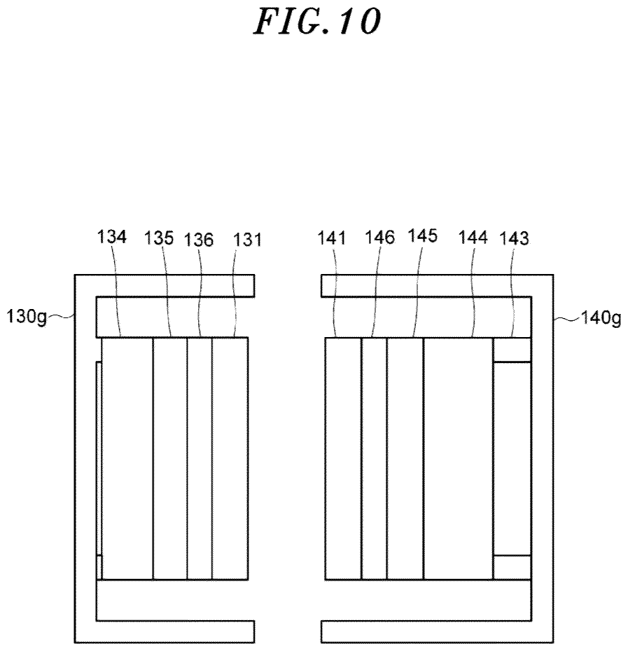

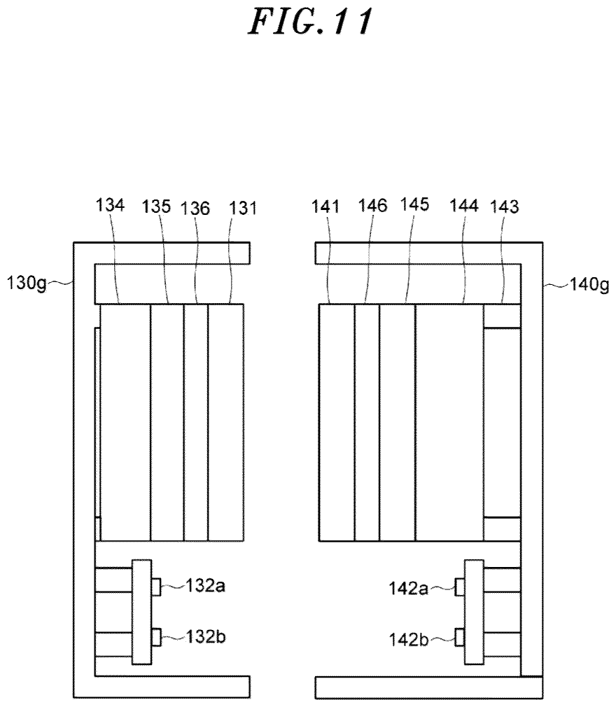

As shown in FIGS. 10 and 11, the power transmitting coil unit 130 may further include a metal housing 130g. The metal housing 130g has an open end, and is grounded. The power transmitting coil 131 is disposed in the metal housing 130g while ensuring an insulation distance. The power transmitting coil unit 130 may further include a heat sink 134, a ferrite material 135, and a thermally conductive sheet 136. The heat sink 134 is disposed in the metal housing 130g, and is supported by the metal housing 130g. The ferrite material 135 is disposed on the heat sink 134. The thermally conductive sheet 136 is disposed on the ferrite material 135. The power transmitting coil 131 is disposed on the thermally conductive sheet 136, and faces the power receiving coil 141 via the open end of the metal housing 130g. As shown in FIG. 11, the resonant capacitor 132a and the resonant capacitor 132b may further be accommodated in the metal housing 130g.

As shown in FIG. 9, the power receiving coil unit 140 includes a receiving coil 141. The power receiving coil 141 is electromagnetically inductively coupled to the power transmitting coil 131. The power receiving coil unit 140 may include a resonant capacitor 142a and a resonant capacitor 142b, in addition to the power receiving coil 141. The resonant capacitor 142a is connected between one of a pair of power supply lines extending from the power receiving coil unit 140 and one end of the power receiving coil 141. The resonant capacitor 142b is connected between the other of the pair of power supply lines and the other end of the power receiving coil 141. The power receiving coil 141, the resonant capacitor 142a, and the resonant capacitor 142b constitute a resonant circuit for the transmission frequency. In other words, the power receiving coil 141, the resonant capacitor 142a, and the resonant capacitor 142b have a resonant frequency that is substantially equal to the transmission frequency. The power receiving coil unit 140 may not include any one of the resonant capacitor 142a and the resonant capacitor 142b.

As shown in FIGS. 10 and 11, the power receiving coil unit 140 may further include a metal housing 140g. The metal housing 140g has an open end, and is grounded. The power receiving coil 141 is disposed in the metal housing 140g while ensuring an insulating distance. The power receiving coil unit 140 may further include a spacer 143, a heat sink 144, a ferrite material 145, and a thermally conductive sheet 146. The spacer 143 is disposed the metal housing 140g, and is supported by the metal housing 140g. The spacer 143 will be described later. The heat sink 144 is disposed on the spacer 143. The ferrite material 145 is disposed on the heat sink 144. The thermally conductive sheet 146 is disposed on the ferrite material 145. The power receiving coil 141 is disposed on the thermally conductive sheet 146, and faces the power transmitting coil 131 via the open end of the metal housing 140g. As shown in FIG. 11, a resonant capacitor 142a and a resonant capacitor 142b may be further accommodated in the metal housing 140g.

The spacer 143 is made of a dielectric material, and is provided between the power receiving coil 141 and the metal housing 140g (ground). The spacer 143 applies a spatial stray capacitance to the gap between the power receiving coil 141 and the ground.

### (1260 Characteristics of Power Receiving Coil Unit)

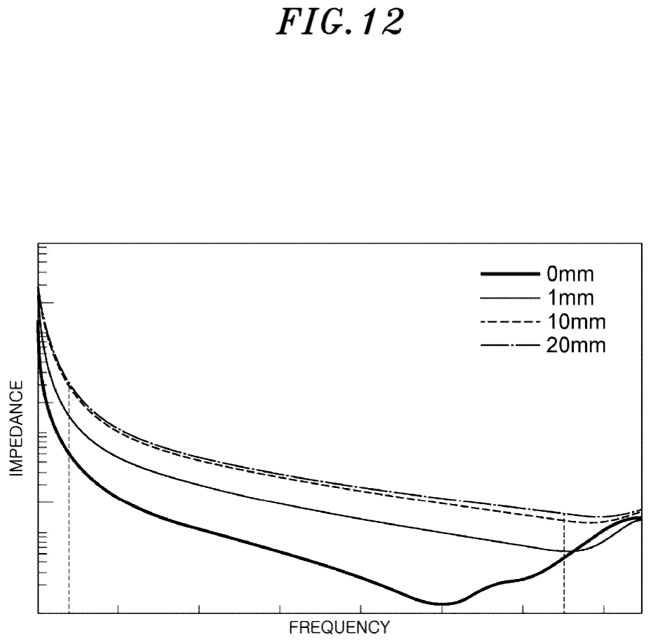

Hereinafter, FIG. 12 will be referred to. FIG. 12 is a graph showing impedance characteristics of the power receiving coil unit according to one exemplary embodiment. FIG. 12 shows impedance characteristics of the power receiving coil unit 140 according to the thickness of the spacer 143. The thickness of the spacer 143 corresponds to the distance between the heat sink 144 and the metal housing 140g. As shown in FIG. 12, the power receiving coil unit 140 can adjust the impedance of each of frequencies f_{H} and f_{L} according to the thickness of the spacer 143. Therefore, in the power receiving coil unit 140, it is possible to provide a high impedance at each of the two frequencies of the RF power used in the plasma processing apparatus, such as the first RF signal and the second RF signal. Since a high impedance can be obtained in the power receiving coil unit 140, it is possible to suppress the loss of the RF power and obtain a high processing rate (e.g., an etching rate).

### (RF Filter 200)

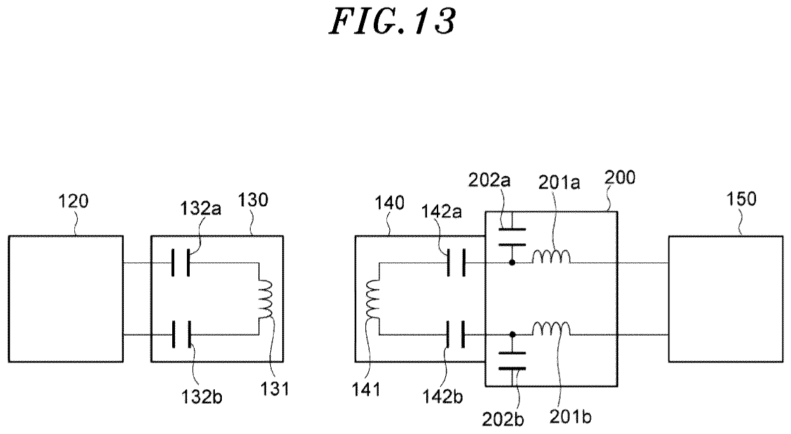

Hereinafter, FIG. 13 will be referred to. FIG. 13 is a diagram showing an RF filter according to one exemplary embodiment. As shown in FIG. 13, the RF filter 200 is connected between the power receiving coil unit 140 and the rectifying and smoothing unit 150. The RF filter 200 includes an inductor 201a, an inductor 201b, a termination capacitor 202a, and a termination capacitor 202b. One end of the inductor 201a is connected to the resonant capacitor 142a, and the other end of the inductor 201a is connected to the rectifying and smoothing unit 150. One end of the inductor 201b is connected to the resonant capacitor 142b, and the other end of the inductor 201b is connected to the rectifying and smoothing unit 150. The termination capacitor 202a is connected between one end of the inductor 201a and the ground. The termination capacitor 202b is connected between one end of the inductor 201b and the ground. The inductor 201a and the termination capacitor 202a form a low-pass filter. Further, the inductor 201b and the terminating capacitor 202b form a low-pass filter. By using the RF filter 200, the high impedance can be obtained at each of the two frequencies of the RF power used in the plasma processing apparatus, such as the first RF signal and the second RF signal. Accordingly, the loss of the RF power can be suppressed, and a high processing rate (e.g., etching rate) can be obtained.

### (Rectifying and Smoothing Unit)

Hereinafter, FIG. 14 will be referred to. FIG. 14 is a diagram showing a rectifying and smoothing unit according to one exemplary embodiment. In one embodiment, the rectifying and smoothing unit 150 includes a controller 152, a rectifying circuit 153, and a smoothing circuit 154. The rectifying circuit 153 is connected between the power receiving coil unit 140 and the smoothing circuit 154. The smoothing circuit 154 is connected between the rectifying circuit 153 and the power storage unit 160. The controller 152 includes a processor such as a CPU or a programmable logic device such as a field-programmable gate array (FPGA). The controller 152 may be the same as or different from the controller 122.

The rectifying circuit 153 outputs the power generated by full-wave rectification of the AC power from the power receiving coil unit 140. The rectifying circuit 153 is, for example, a diode bridge. Further, the rectifying circuit 153 may output the power generated by half-wave rectification of the AC power from the power receiving coil unit 140.

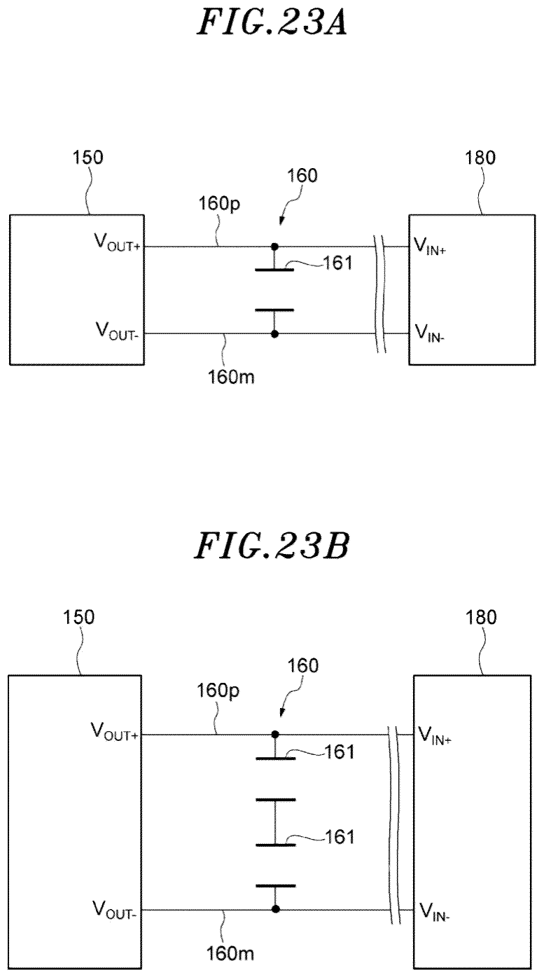

The smoothing circuit 154 generates the DC power by smoothing the power from the rectifying circuit 153. The smoothing circuit 154 may include an inductor 1541a, a capacitor 1542a, and a capacitor 1542b. One end of the inductor 1541a is connected to one of a pair of inputs of the smoothing circuit 154. The other end of the inductor 1541a is connected to a positive output V_{OUT+} of the rectifying and smoothing unit 150. The positive output of the rectifying and smoothing unit 150 is connected to one end of each of one or more capacitors of the power storage unit 160 via a positive line 160p (see FIGS. 23A and 23B) of a pair of power supply lines to be described later.

One end of the capacitor 1542a is connected to one of the pair of inputs of the smoothing circuit 154 and one end of the inductor 1541a. The other end of the capacitor 1542a is connected to the other of the pair of outputs of the smoothing circuit 154 and a negative output V_{OUT-} of the rectifying and smoothing unit 150. The negative output of the rectifying and smoothing unit 150 is connected to the other end of each of one or more capacitors of the power storage unit 160 via a negative line 160m (see FIGS. 23A and 23B) of a pair of power supply lines to be described below. One end of the capacitor 1542b is connected to the other end of the inductor 1541a. The other end of the capacitor 1542b is connected to the other of the pair of outputs of the smoothing circuit 154 and the negative output V_{OUT-} of the rectifying and smoothing unit 150.

The rectifying and smoothing unit 150 may further include a voltage detector 155v and a current detector 155i. The voltage detector 155v detects a voltage value between the positive output and the negative output of the rectifying and smoothing unit 150. The current detector 155i detects a current value between the rectifying and smoothing unit 150 and the power storage unit 160. The voltage value detected by the voltage detector 155v and the current value detected by the current detector 155i are notified to the controller 152. The controller 152 generates the above-described instruction signal according to the power stored in the power storage unit 160. For example, when the power stored in the power storage unit 160 is less than or equal to than a first threshold, the controller 152 generates an instruction signal for instructing the power transmitting unit 120 to start power supply, i.e., to output the transmission AC power. The first threshold is, for example, a consumption power in a load such as the power-consuming member 240. The second threshold value may be a value obtained by multiplying the consumption power of the load such as the power-consuming member 240 by a certain value (for example, a value within the range of 1 to 3) in consideration of tolerance. On the other hand, when the power stored in power storage unit 160 is greater than the second threshold value, the controller 152 generates an instruction signal for instructing the power transmitting unit 120 to stop the power supply, i.e., to stop outputting the transmission AC power. The second threshold value is a value that does not exceed the limit storage power of the power storage unit 160. The second threshold value is, for example, a value obtained by multiplying the limit storage power of the power storage unit 160 by a certain value (for example, a value less than or equal to 1).

The rectifying and smoothing unit 150 includes the communication part 151 described above. The communication part 151 includes a driver 151d, a transmitter 151tx, and a receiver 151rx. The transmitter 151tx is a transmitter of a wireless signal or a transmitter of an optical signal. The receiver 151rx is a receiver of a wireless signal or a receiver of an optical signal. In the communication part 151. the transmitter 151tx is driven by the driver 151d to output a signal from the controller 122, such as an instruction signal, from the transmitter 151tx as a wireless signal or an optical signal. The signal outputted from the transmitter 151tx is received by the communication part 121 of the power transmitting unit 120. In addition, in the communication part 151, the receiver 151rx receives a signal from the communication part 121, and the received signal is inputted to the controller 152 via the driver 151d.

### (RF Filter 190)

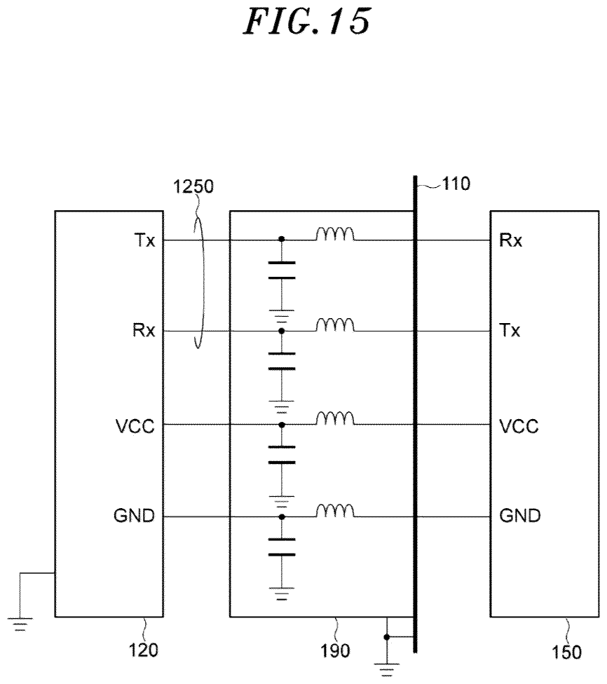

Hereinafter, FIG. 15 will be referred to. FIG. 15 is a diagram showing an RF filter 190 according to one exemplary embodiment. As shown in FIG. 15, the signal line 1250 may include a first signal line that electrically connects a signal output Tx of the power transmitting unit 120 and a signal input Rx of the rectifying and smoothing unit 150, and a second signal line that electrically connects a signal input Rx of the power transmitting unit 120 and a signal output Tx of the rectifying and smoothing unit 150. The signal line 1250 may include a signal line that connects a first reference voltage terminal VCC of the power transmitting unit 120 and a first reference voltage terminal VCC of the rectifying and smoothing unit 150, and a signal line that connects a second reference voltage terminal GND of the power transmitting unit 120 and a second reference voltage terminal GND of the rectifying and smoothing unit 150. The signal line 1250 may be a shielded cable covered with a shield of ground potential. In this case, the plurality of signal lines constituting the signal line 1250 may be individually covered with a shield, or may be collectively covered with a shield. The RF filter 190 provides a low-pass filter for each of the plurality of signal lines constituting the signal line 1250. The low-pass filter may be an LC filter including an inductor and a capacitor. The inductor of the low-pass filter constitutes a part of the corresponding signal line. The capacitor is connected between one end of the inductor connected to the power transmitting unit 120 and the ground. By using the RF filter 190, it is possible to suppress the propagation of the RF power (RF noise) through the signal line 1250 between the rectifying and smoothing unit 150 and the power transmitting unit 120.

### (Communication Part of Power Transmitting Unit and Communication Part of Rectifying and Smoothing Unit)

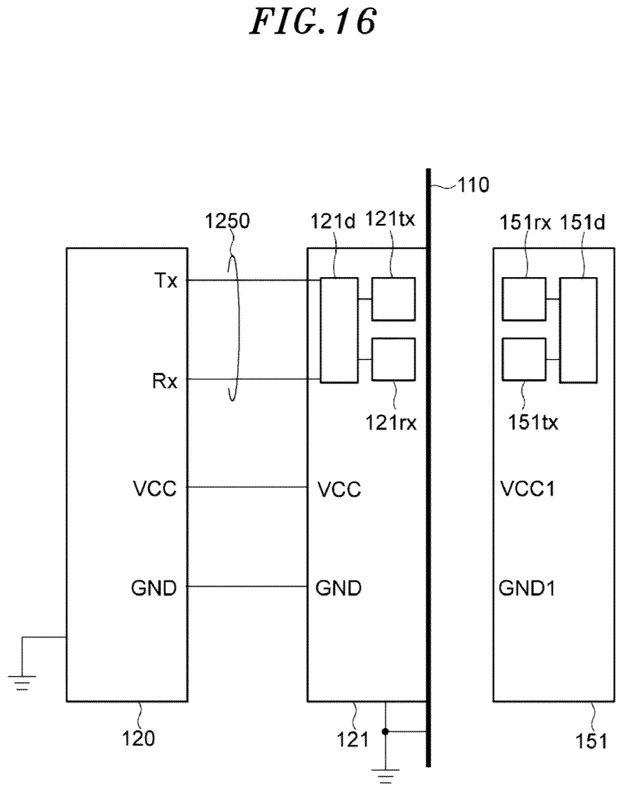

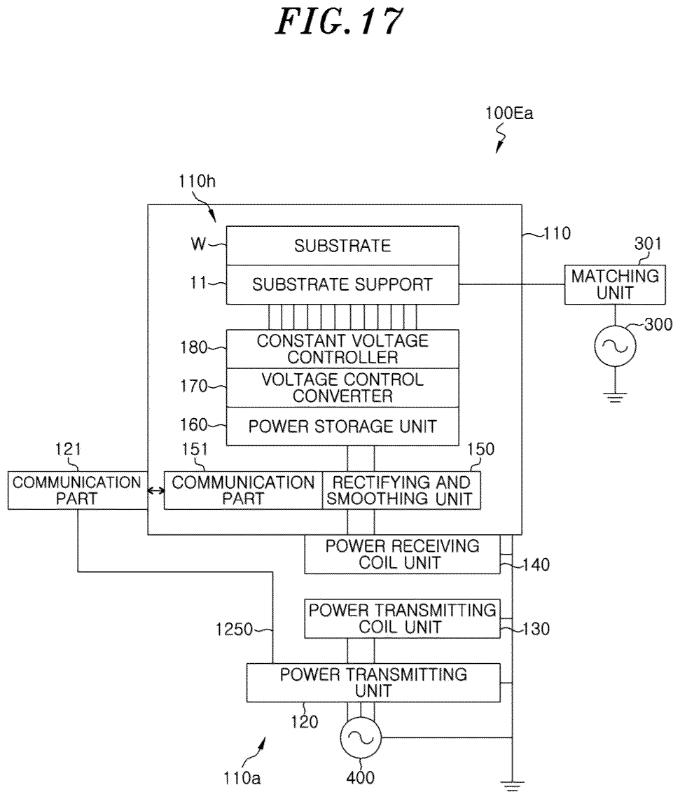

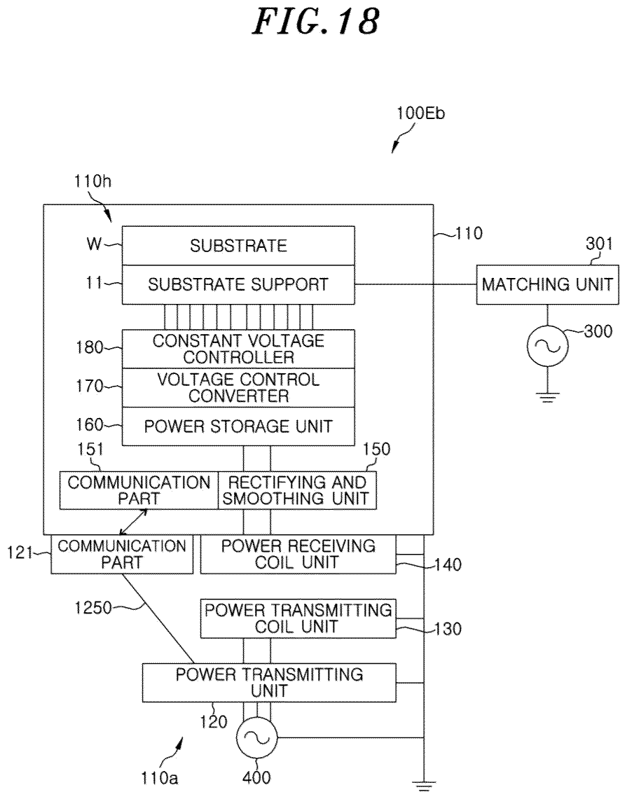

Hereinafter, FIGS. 16 to 18 will be referred to. FIG. 16 is a diagram showing a communication part of the power transmitting unit and a communication part of the rectifying and smoothing unit according to one exemplary embodiment. FIGS. 17 and 18 are diagrams showing a plasma processing apparatus according to still another exemplary embodiment. As shown in FIGS. 6, 7, 16, 17, and 18, the communication part 121 and the communication part 151 may be configured to transmit a signal such as the above-described instruction signal to each other by wireless communication. The transmission using wireless communication may be performed by optical communication. When the communication part 121 and the communication part 151 transmit a signals to each other by wireless communication, the communication part 121 and the communication part 151 may be located at any positions as long as there is no shield therebetween. In the example shown in FIGS. 16 to 18, the RF filter 190 is not necessary. In various exemplary embodiments including the examples shown in FIGS. 16 to 18, the signal line 1250 may be a shielded cable covered with a shield of ground potential. In this case, the plurality of signal lines constituting the signal line 1250 may be individually covered with a shield or may be collectively covered with a shield.

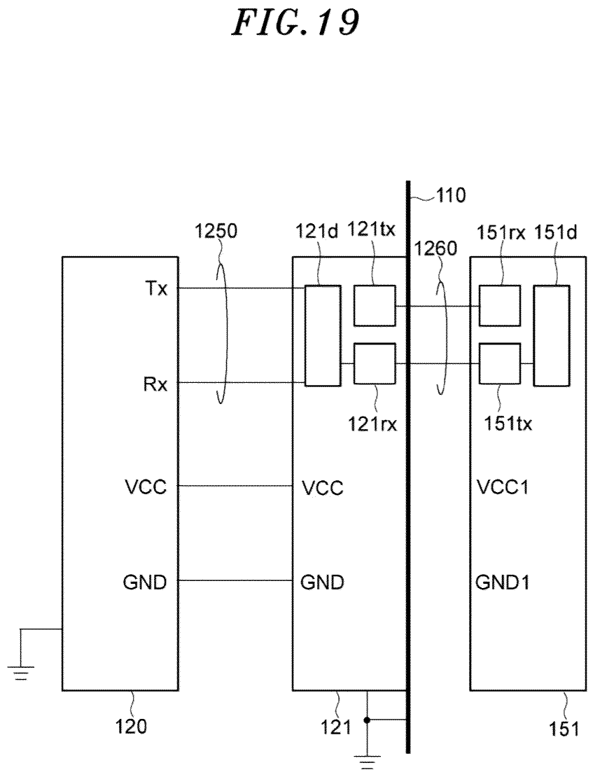

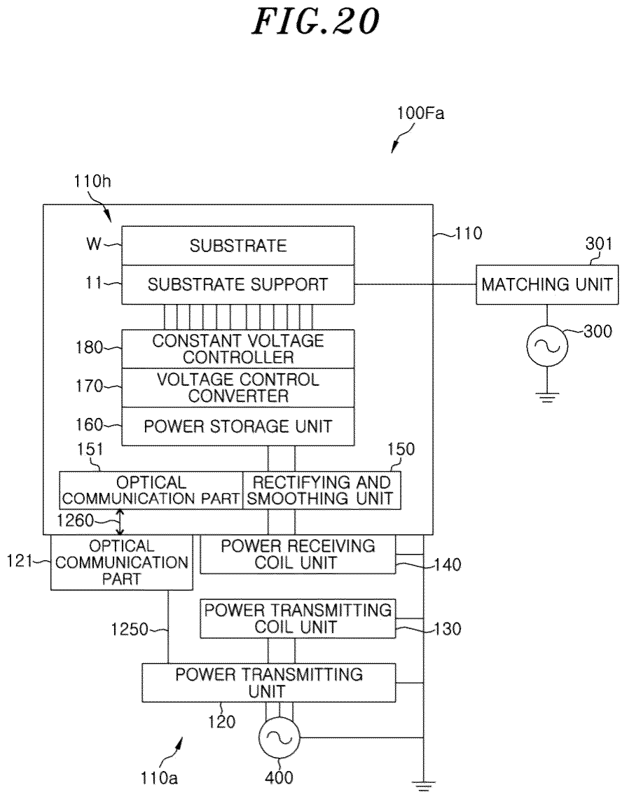

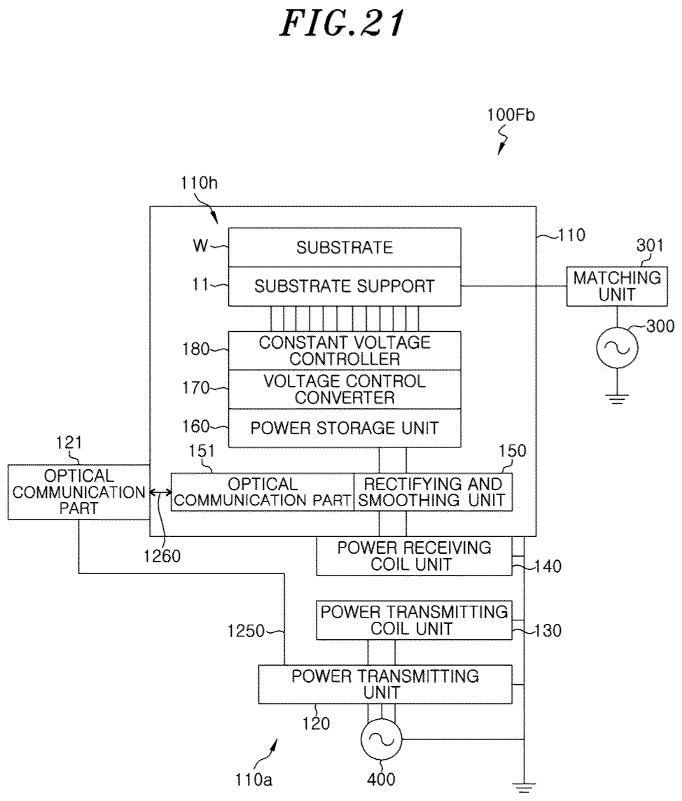

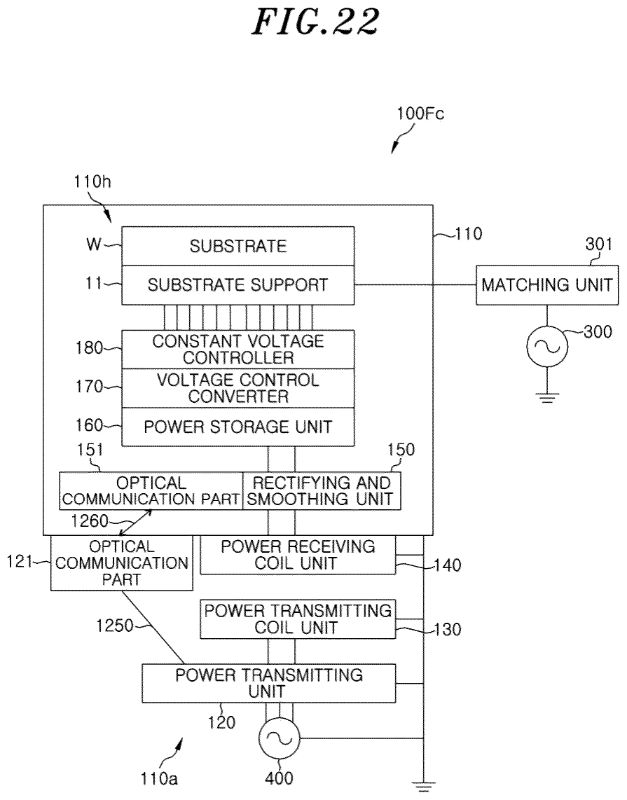

Hereinafter, FIGS. 19 to 22 will be referred to. FIG. 19 is a diagram showing a communication part of the power transmitting unit and a communication part of the rectifying and smoothing unit according to another exemplary embodiment. FIGS. 20 to 22 are diagrams showing a plasma processing apparatus according to still another exemplary embodiment. As shown in FIGS. 19 to 22, the communication part 121 and the communication part 151 may be configured to transmit a signal (optical signal) such as the above-described instruction signal to each other through the optical fiber 1260, that is, by optical fiber communication. When the communication part 121 and the communication part 151 transmit a signal to each other through the optical fiber 1260, the communication part 121 and the communication part 151 may be located at any position as long as the bending radius of the optical fiber 1260 is within an allowable range. Also in the examples shown in FIGS. 19 to 22, the RF filter 190 is not necessary.

### (Power Storage Unit)

Hereinafter, FIGS. 23A and 23B will be referred to. FIGS. 23A and 23B are diagrams showing a power storage unit according to one exemplary embodiment. As shown in FIG. 23A, the power storage unit 160 includes a capacitor 161. The capacitor 161 is connected between the pair of power supply lines, i.e., the positive line 160p and the negative line 160m. The positive line 160p extends from the positive output V_{OUT+} of the rectifying and smoothing unit 150 toward the load. The negative line 160m extends from the negative output V_{OUT-} of the rectifying and smoothing unit 150 toward the load. The capacitor 161 may be a polarized capacitor. The capacitor 161 may be an electric double layer or a lithium ion battery.

As shown in FIG. 23B, the power storage unit 160 may include a plurality of capacitors 161. The plurality of capacitors 161 are connected in series between the positive line 160p and the negative line 160m. The plurality of capacitors 161 may have the same capacitance, or may have different capacitances. Each of the plurality of capacitors 161 may be a polarized capacitor. Each of the plurality of capacitors 161 may be an electric double layer or a lithium ion battery. The power storage unit 160 needs to be used under the condition in which the sum of the input voltage thereto and the line potential difference due to normal mode noise is lower than the allowable input voltage. When the power storage unit 160 includes the plurality of capacitors 161 connected in series, the allowable input voltage of the power storage unit 160 is increased. Therefore, in the example shown in FIG. 23B, the noise resistance of the power storage unit 160 is improved.

### (Voltage Control Converter)

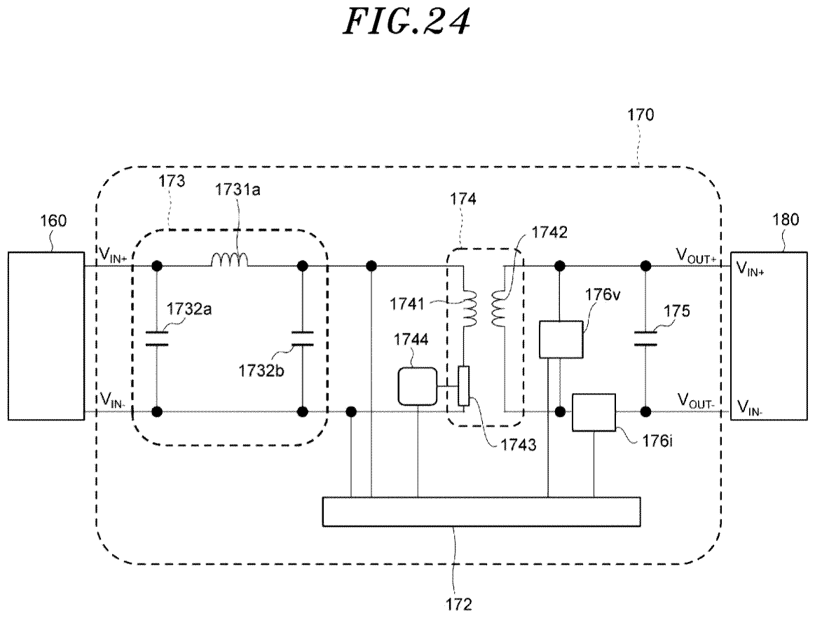

Hereinafter, FIG. 24 will be referred to. FIG. 24 is a diagram showing a voltage control converter according to one exemplary embodiment. The voltage control converter 170 is a DC-DC converter. The voltage control converter 170 is connected between the power storage unit 160 and the constant voltage controller 180. The positive line 160p is connected to the positive input V_{IN+} of the voltage control converter 170. The negative line 160m is connected to the negative input V_{IN-} of the voltage control converter 170. The positive output V_{OUT+} of the voltage control converter 170 is connected to the positive input V_{IN+} of the constant voltage controller 180. The negative output V_{OUT-} of the voltage control converter 170 is connected to the negative input V_{IN-} of the constant voltage controller 180.

The voltage control converter 170 may include a controller 172, a low-pass filter 173, a transformer 174, and a capacitor 175. The low-pass filter 173 may include an inductor 1731a, a capacitor 1732a, and a capacitor 1732b. One end of the inductor 1731a is connected to the positive input V_{IN+} of the voltage control converter 170. The other end of the inductor 1731a is connected to one end of the primary coil of the transformer 174. One end of the capacitor 1732a is connected to one end of the inductor 1731a and the positive input V_{IN+} of the voltage control converter 170. The other end of the capacitor 1732a is connected to the negative input V_{IN-} of the voltage control converter 170. One end of the capacitor 1732b is connected to the other end of the inductor 1731a. The other end of the capacitor 1732b is connected to the negative input V_{IN-}.

The transformer 174 includes a primary coil 1741, a secondary coil 1742, and a switch 1743. The other end of the primary coil 1741 is connected to the negative input V_{IN-} of the voltage control converter 170 via the switch 1743. One end of the secondary coil 1742 is connected to one end of the capacitor 175 and the positive output V_{OUT+} of the voltage control converter 170. The other end of the secondary coil 1742 is connected to the other end of the capacitor 175 and the negative output V_{OUT-} of the voltage control converter 170.

A driver 1744 is connected to the switch 1743. The driver 1744 opens and closes the switch 1743. When the switch 1743 is closed, that is, when the other end of the primary coil 1741 and the negative input V_{IN-} are in a conductive state, the other end of the primary coil 1741 is connected to the negative input V_{IN-} of the voltage control converter 170, and the DC power from the voltage control converter 170 is provided to the constant voltage controller 180. On the other hand, when the switch 1743 is opened, that is, when the other end of the primary coil 1741 and the negative input V_{IN-} are in a non-conductive state, the connection between the other end of the primary coil 1741 and the negative input V_{IN-} of the voltage control converter 170 is cut off, and the supply of the DC power from the voltage control converter 170 to the constant voltage controller 180 is interrupted.

The voltage control converter 170 may further include a voltage detector 176v and a current detector 176i. The voltage detector 176v detects a voltage value between both ends of the secondary coil 1742 or a voltage value between the positive output and the negative output of the voltage control converter 170. The current detector 176i measures a current value between the other end of the secondary coil 1742 and the negative output of the voltage control converter 170. The voltage value detected by the voltage detector 176v and the current value detected by the current detector 176i are notified to the controller 172. The controller 172 may be the same as or different from at least one of the controller 122 and the controller 152.

When the voltage value detected by the voltage detector 176v is greater than or equal to a threshold value, the controller 172 controls the driver 1744 to cut off the supply of the DC power from the voltage control converter 170 to the constant voltage controller 180. The voltage value between the positive output and the negative output of the voltage control converter 170 is the sum of the output voltage value of the voltage control converter 170 and the line potential difference due to normal mode noise. In the present embodiment, it is possible to suppress damages to the load of the voltage control converter 170 due to an overvoltage caused by the line potential difference due to normal mode noise.

### (Constant Voltage Controller)

Hereinafter, FIGS. 25 and 26 will be referred to. FIGS. 25 and 26 are diagrams illustrating constant voltage controllers according to some exemplary embodiments. The constant voltage controller 180 is connected between the power storage unit 160 and at least one power-consuming member 240, and is configured to control start and stop of the application of the voltage (the application of the direct current voltage) to at least one power-consuming member 240.

The constant voltage controller 180 includes a controller 182 and at least one switch 183. The positive input V_{IN+} of the constant voltage controller 180 is connected to the power-consuming member 240 via the switch 183. The negative input V_{IN-} of the constant voltage controller 180 is connected to the power-consuming member 240. The switch 183 is controlled by the controller 182. When the switch 183 is closed, the DC voltage from the constant voltage controller 180 is applied to the power-consuming member 240. When the switch 183 is opened, the application of the DC voltage from the constant voltage controller 180 to the power-consuming member 240 is stopped. Further, the controller 182 may be the same as or different from at least one of the controllers 122, 152, and 172.

In the embodiment shown in FIGS. 25 and 26, the plasma processing apparatus includes a plurality of power-consuming members 240. The constant voltage controller 180 includes the controller 182 and the plurality of switches 183. The positive input V_{IN+} of the constant voltage controller 180 is connected to the plurality of power-consuming members 240 via the plurality of switches 183. The negative input V_{IN-} of the constant voltage controller 180 is connected to the plurality of power-consuming members 240.

In the embodiment shown in FIGS. 25 and 26, the power-consuming members 240 may include a plurality of heaters (resistance heating elements). The heaters may be provided in the substrate support 11. In the embodiment shown in FIG. 25, a plurality of resistors 260 are disposed near the heaters. Each of the resistors 260 has a resistance value that varies depending on a temperature. Each of the resistors 260 is, for example, a thermistor. Each of the resistors 260 is connected in series with a reference resistor (not shown). The constant voltage controller 180 includes a plurality of measuring parts 184. Each of the measuring parts 184 applies a reference voltage to the series connection between a corresponding resistor among the resistors 260 and a reference resistor to detect a voltage value between both ends of the resistor. Each of the measuring parts 184 notifies the detected voltage value to the controller 182 of. The controller 182 identifies the temperature of the region in which the corresponding heater is located from the notified voltage value, and controls the application of the DC voltage to the corresponding heater such that the temperature of the region becomes close to a target temperature. Further, the optical fiber thermometer may be provided instead of the plurality of resistors 260. In this case, wiring between the plurality of resistors 260 and the plurality of measuring parts 184 is not required, so that the influence of the RF conductive noise on the power-consuming member 240 can be eliminated.

In the embodiment shown in FIG. 26, the constant voltage controller 180 includes a voltage detector 185v and a plurality of current detectors 185i. The voltage detector 185v detects a voltage value applied to each of the plurality of heaters. The plurality of current detectors 185i measure a current value, i.e., a value of a current supplied to a corresponding heater among the plurality of heaters. The plurality of measuring parts 184 identify the resistance value of the corresponding heater among the plurality of heaters from the current value detected by the corresponding current detector among the plurality of current detectors 185i and the voltage value detected by the voltage detector 185v. The controller 182 identifies a temperature of each of a plurality of regions in which the plurality of heaters are disposed from the detected resistance value of each of the plurality of heaters. The controller 182 controls the application of the DC voltage to each of the plurality of heaters such that the temperature of each of the plurality of regions becomes close to a target temperature.

### (Power Supply Using No Power Storage Unit)

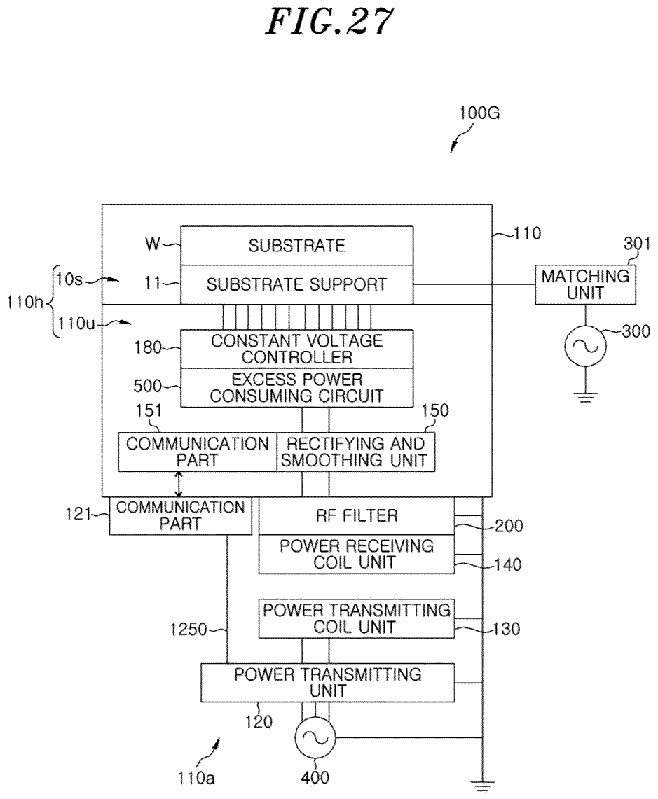

Hereinafter, FIG. 27 will be referred to. FIG. 27 is a diagram schematically showing a plasma processing apparatus according to still another exemplary embodiment. Hereinafter, the differences between a plasma processing apparatus 100G shown in FIG. 27 and the plasma processing apparatus 100E shown in FIG. 7 will be described.

The plasma processing apparatus 100G does not include the power storage unit 160. In the plasma processing apparatus 100G, the rectifying and smoothing unit 150 is connected to the constant voltage controller 180 without passing through the power storage unit 160 and the voltage control converter 170. In other words, in the plasma processing apparatus 100E, the power generated by the rectifying and smoothing unit 150 is supplied from the constant voltage controller 180 to at least one power-consuming member 240 without passing through the power storage unit 160 and the voltage control converter 170.

As described above, the constant voltage controller 180 controls start and stop of the application of the voltage to each of the plurality of power-consuming members 240. Therefore, in the plasma processing apparatus 1, the load that receives the power from the rectifying and smoothing unit 150 via the constant voltage controller 180 varies. In other words, a load resistance value R_{L} varies. In order to supply the power according to the load resistance value R_{L} to the load, the controller 122 of the power transmitting unit 120 detects an input impedance Zᵢₙ of the power transmitting unit 120. As a result, the controller 122 detects the load variation, determines a required power level corresponding to the input impedance Zᵢₙ or the load resistance value R_{L}, and adjusts the output power from the power transmitting unit 120.

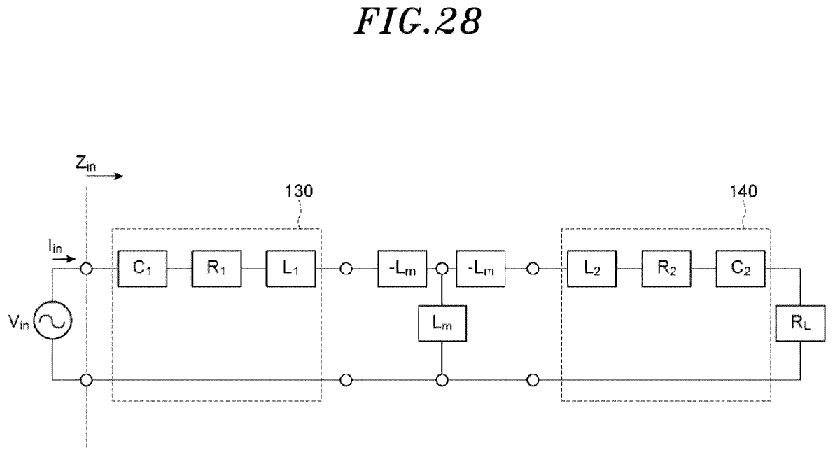

Hereinafter, FIG. 28 will be referred to. FIG. 28 is a diagram showing an example of an equivalent circuit of the power transmitting coil unit and the power receiving coil unit in a state where the resonance occurs at the transmission frequency of the power transmitted from the power transmitting unit 120 and the phase difference between the input voltage Vᵢₙ and the input current Iᵢₙ is zero (power factor 100%). As shown in FIG. 28, for example, the equivalent circuit of the power transmitting coil unit and the power receiving coil includes the power transmitting coil 131 having a self-inductance L₁, a load resistor of the power transmitting coil 131 having the load resistance value R₁, a resonance capacitor of the power transmitting coil unit 130 having a capacitance C₁, three inductors between the power transmitting coil 131 and the power receiving coil 141 having a mutual inductance Lₘ, the power receiving coil 141 having a self-inductance L₂, a load resistor of the power receiving coil 141 having a load resistance value R₂, and a resonant capacitor of the power receiving coil unit 140 having a capacitance C₂. In the equivalent circuit of FIG. 28, Zᵢₙ indicates the input impedance of the power transmitting unit 120, Vᵢₙ indicates the input voltage from the power transmitting unit 120 to the power transmitting coil unit 130, and Iᵢₙ indicates the input current from the power transmitting unit 120 to the power transmitting coil unit 130. According to the equivalent circuit of FIG. 28, the input impedance Zᵢₙ is defined by the following Eq. (1).

Zᵢₙ=Vᵢₙ/Iᵢₙ=R₁+(2πfLₘ)²/(R₂+R_{L}) Eq. (1)

In Eq. (1), f indicates the transmission frequency of the power transmitted from the power transmitting unit 120.

The controller 122 obtains the effect value of the input voltage Vᵢₙ from the voltage measured by the voltage detector 126v, and obtains the effective value of the input current Iᵢₙ from the current measured by the current detector 126i. The controller 122 can obtain the input impedance Zᵢₙ from the input voltage Vᵢₙ and the input current Iᵢₙ based on Eq. (1). The controller 122 may further obtain the load resistance value R_{L} from the input impedance Zᵢₙ based on Eq. (1).

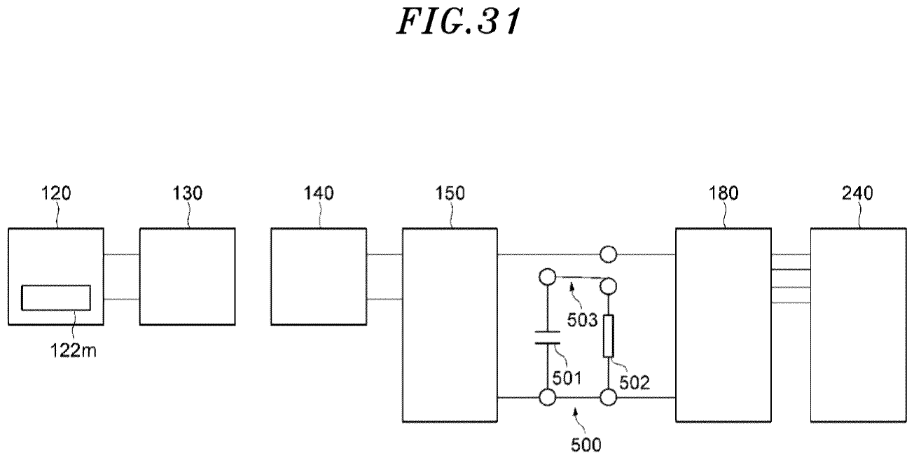

The controller 122 calculates the required power level corresponding to the parameter value such as the input impedance Zᵢₙ or the load resistance value R_{L} by using at least one table. The controller 122 may identify a peak value V_{P} of the output voltage Vₒᵤₜ of the power transmitting unit 120, a duty ratio Duty of the output voltage Vₒᵤₜ, and an amplitude I_{A} of the output current Iₒᵤₜ as parameters for identifying the required power level of the output power from the power transmitting unit 120. Further, at least one table is stored in a storage device 122m (see FIG. 31), such as a memory device, connected to the controller 122. The storage device 122m may be a part of the power transmitting unit 120.

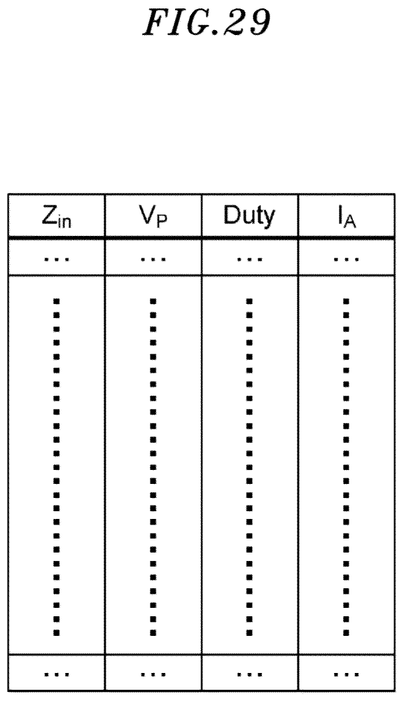

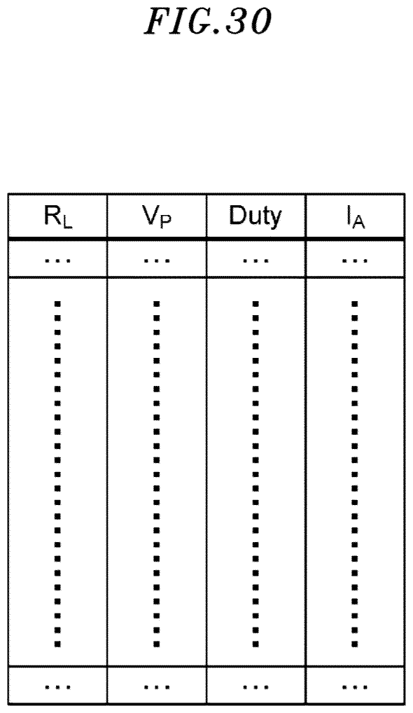

FIGS. 29 and 30 are diagrams showing an example of at least one of the above-described tables. When the distance (gap length) between the power transmitting coil 131 and the power receiving coil 141 is fixed, the controller 122 may use a single table stored in the storage device 122m. As shown in FIG. 29, the table stores the peak value V_{P}, the duty ratio Duty, and the amplitude I_{A} in association with the input impedance Zᵢₙ. The controller 122 can identify the required power level corresponding to the input impedance Zᵢₙ, i.e., the peak value V_{P}, the duty ratio Duty, and the amplitude I_{A}, by referring to the table shown in FIG. 29 using the input impedance Zᵢₙ as a key. The controller 122 controls each component of the power transmitting unit 120 to output the output power having the peak value V_{P} and the duty ratio Duty of the output voltage Vₒᵤₜ and the amplitude I_{A} of the output current Iₒᵤₜ.

Alternatively, when the transmission frequency f, the mutual inductance Lₘ, the load resistance value R₁, and the load resistance value R₂ are stored in the memory device 122m, the controller 122 may calculate the load resistance value R₁ from the transmission frequency f, the mutual inductance Lₘ, the load resistance value R₁, the load resistance value R₂, and the input impedance Zᵢₙ based on Eq. (1). Further, 2πf may be stored, instead of the transmission frequency f, in the memory device 122m. Further, the self-inductance L₁ of the power transmitting coil 131, the self-inductance L₂ Of the power receiving coil 141, and a coupling coefficient k between the power transmitting coil 131 and the power receiving coil 141 may be stored, instead of the mutual inductance Lₘ, in the memory device 122. The controller 122 may calculate the mutual inductance Lₘ from the self-inductance L₁, the self-inductance L₂, and the coupling coefficient k. Alternatively, 2πfLₘ or (2πfLₘ)² may be stored, instead of the transmission frequency f and the mutual inductance Lₘ, in the storage device 122m.

Further, as shown in FIG. 30, the table stores the peak value V_{P}, the duty ratio Duty, and the amplitude I_{A} in association with the load resistance value R_{L}. The controller 122 can identify the required power level corresponding to the load resistance value R_{L}, i.e., the peak value V_{P}, the duty ratio Duty, and the amplitude I_{A}, by referring to the table shown in FIG. 30 using the load resistance value R_{L} as a key. The controller 122 controls each component of the power transmitting unit 120 to output the output power having the peak value V_{P} and the duty ratio Duty of the output voltage Vₒᵤₜ and the amplitude I_{A} of the output current Iₒᵤₜ.

Further, then the distance (gap length) between the power transmitting coil 131 and the power receiving coil 141 is variable as will be described below, the storage device 122m stores a plurality of tables similar to the table shown in FIG. 29 or 30. The plurality of tables are prepared for each of a plurality of settable distances between the power transmitting coil 131 and the power receiving coil 141. The controller 122 can select a table to be used depending on the current distance between the power transmitting coil 131 and the power receiving coil 141.

As described above, in the plasma processing apparatus 100G, the power can be supplied by electromagnetic induction coupling without passing through the power storage unit in accordance with the load resistance value R_{L} of the power-consuming member 240. In other words, in the plasma processing apparatus 100G, the power corresponding to the variation in the load resistance value R_{L} of the power-consuming member 240 (hereinafter, may be referred to as “load variation”) can be supplied by electromagnetic induction coupling without passing through the power storage unit.

Further, the controller 122 can identify the variation in the load resistance value R_{L} by calculating the input impedance Zᵢₙ, so that a power change instruction may not be issued from the constant voltage controller 180 via the communication part 151 and the communication part 121. Since, however, the load variation is caused by the constant voltage controller 180, the power change instruction may be notified in advance from the constant voltage controller 180 to the controller 122 via the communication part 151 and the communication part 121 before the load variation occurs. Further, the load variation may be caused by the constant voltage controller 180 at a timing synchronized with the output power having the transmission frequency f outputted from the power receiving coil unit 140. Specifically, a synchronization signal synchronized with the output power having the transmission frequency f from the power receiving coil unit 140 may be generated by the rectifying and smoothing unit 150, and the constant voltage controller 180 may cause the load variation at the timing synchronized with the output power using the synchronization signal. Further, the load variation may be set such that it does not occur simultaneously with the change in the distance between the power transmitting coil 131 and the power receiving coil 141.

Hereinafter, FIG. 31 will be referred to together with FIG. 27. FIG. 31 is a diagram schematically illustrating a plasma processing apparatus according to still another exemplary embodiment. As illustrated in FIGS. 27 and 31, the plasma processing apparatus 100G may include an excess power-consuming circuit 500. The excess power-consuming circuit 500 may include a line capacitor 501, an excess power-consuming load 502, and a switching element 503.

The line capacitor 501 can be connected between a pair of power supply lines, i.e., a positive line and a negative line, that connect the rectifying and smoothing unit 150 and the constant voltage controller 180 to each other via the switching element 503. Specifically, one end of the line capacitor 501 is connected to the switching element 503, and the other end of the line capacitor 501 is connected to the negative line.

The excess power-consuming load 502 is a load for consuming the power stored in the line capacitor 501. The excess power-consuming load 502 can consume the power by converting the power into heat. The excess power-consuming load 502 may be provided with a cooling mechanism such as a fan for cooling the excess power-consuming load 502. The excess power-consuming load 502 can be selectively connected to the line capacitor 501 via the switching element 503. One end of the excess power-consuming load 502 is connected to the switching element 503, and the other end of the excess power-consuming load 502 is connected to the negative line.

When the switching element 503 is in an ON state, the connection between the line capacitor 501 and the excess power-consuming load 502 is cut off, and one end of the line capacitor 501 is connected to the positive line. When the switching element 503 is in an OFF state, the connection between the one end of the line capacitor 501 and the positive line is cut off, and one end of the line capacitor 501 is connected to one end of the excess power-consuming load 502. In view of high-speed responsiveness, a semiconductor switching element may be used as the switching element 503.

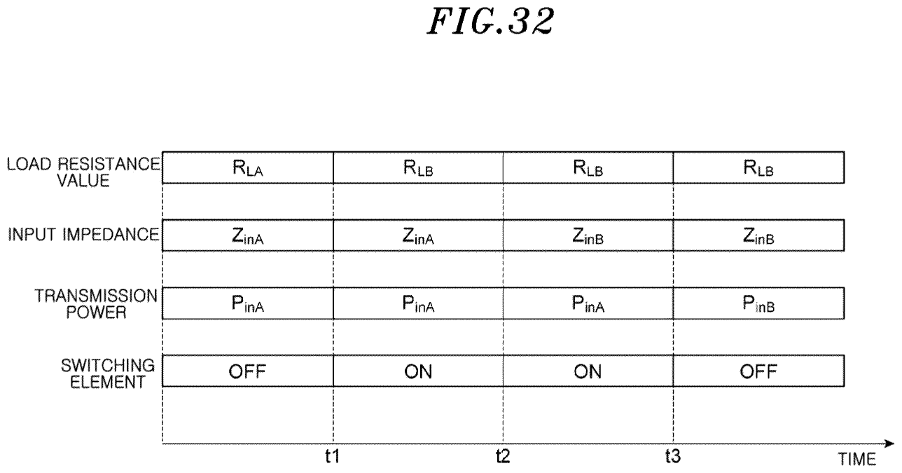

The state of the switching element 503 can be controlled by, for example, the controller 182 of the constant voltage controller 180. Hereinafter, the control of the switching element 503 will be described with reference to FIG. 32. FIG. 32 is an example of a timing chart showing the load resistance value, the input impedance, the transmission power, and the state of the switching element.

The controller 182 of the constant voltage controller 180 sets the state of the switching element 503 to ON when the load variation occurs, particularly when the load resistance value R_{L} decreases. The controller 182 sets the state of the switching element 503 to OFF after the level of the power transmitted from the power transmitting unit 120 is changed to a power level corresponding to the load resistance value R_{L}.

In the example of FIG. 32, at time t1, the load resistance value R_{L} changes from a load resistance value R_{LA} to a load resistance value R_{LB}, and the state of the switching element 503 is changed from OFF to ON. In the example of FIG. 32, the input impedance Zᵢₙ obtained in the controller 122 of the power transmitting unit 120 before time t2 is Z_{inA} corresponding to the load resistance value R_{LA}. Therefore, the transmission power before time t2 is P_{inA}.

In the example of FIG. 32, at time t2, the input impedance Zᵢₙ obtained in the controller 122 of the power transmitting unit 120 at time t2 becomes Z_{inB} corresponding to the load resistance value R_{LB}. Further, in the example of FIG. 32, when the input impedance Z_{inB} is detected, the transmission power changes from P_{inA} to P_{inB} at subsequent time t3, and the state of the switching element 503 is set to OFF.

In the excess power-consuming circuit 500, after the load variation occurs and before the power level is changed, the power is temporarily stored in the line capacitor 501. Hence, the inflow of a large current into the constant voltage controller 180 and the power-consuming member 240 can be suppressed, and damages to the constant voltage controller 180 and the power-consuming member 240 can be suppressed. Further, in the excess power-consuming circuit 500, the power stored in the line capacitor 501 is consumed by the excess power consuming load 502.

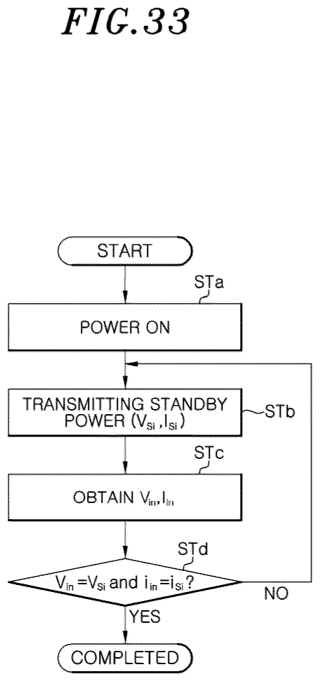

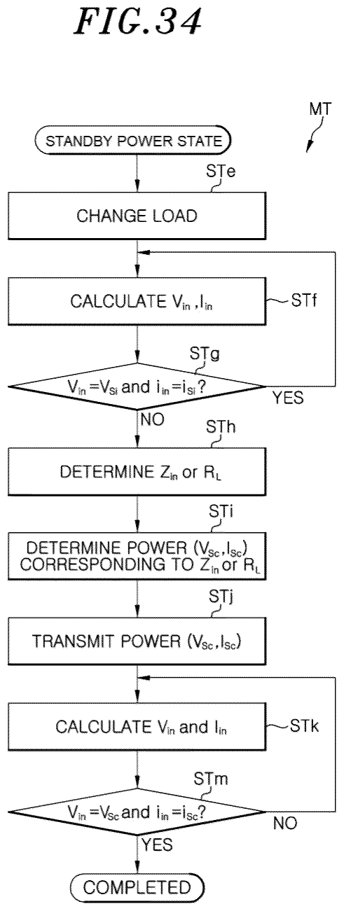

Hereinafter, a power supply method according to one exemplary embodiment will be described with reference to FIGS. 33 and 34. FIGS. 33 and 34 are flowcharts of the power supply method according to one exemplary embodiment. The power supply method (hereinafter, referred to as “method MT”) shown in FIGS. 33 and 34 can be applied to the plasma processing apparatus 100G and plasma processing apparatuses of various exemplary embodiments to be described later.

In step STa of the method MT shown in FIG. 33, the power supply of the plasma processing apparatus is set to ON. In subsequent step STb, a standby power level, i.e., a standby power having a voltage V_{Si} (effective value) and a current I_{Si} (effective value), is transmitted from the power transmitting unit 120. Then, in step STc, the controller 122 obtains an input voltage Vᵢₙ (effective value) and an input current Iᵢₙ (effective value). Then, in step STd, it is determined whether or not the condition that the input voltage Vᵢₙ is equal to the voltage V Si and the input current Iᵢₙ is equal to the current I_{Si} is satisfied. If the condition is not satisfied in step STd, the process from step STb is repeated. If the condition is satisfied in step STd, the standby power state continues. Accordingly, the communication part 151 of the rectifying and smoothing unit 150 is activated, and the communication part 151 and the communication part 121 of the power transmitting unit 120 can communicate with each other. Further, the controller 182 of the constant voltage controller 180 is activated, so that it is possible to monitor the state of the heater and to detect abnormality.

As shown in FIG. 34, when the load varies in step STe in which the standby power state continues, the controller 122 calculates the input voltage Vᵢₙ (effective value) and the input current Iᵢₙ (effective value) in subsequent step STf. In subsequent step STg, it is determined whether or not the condition that the input voltage Vᵢₙ is equal to the voltage V_{Si} and the input current Iᵢₙ is equal to the current I_{Si} is satisfied. If the condition is satisfied in step STg, step STf is repeated.

On the other hand, if the condition is not satisfied in step STg, in subsequent step STh, the input impedance Zᵢₙ or the load resistance value R_{L} is determined by the controller 122. In subsequent step STi, the controller 122 determines the required power level corresponding to the input impedance Zᵢₙ or the load resistance value R_{L}. In subsequent step STj, the power having the required power level is transmitted from the power transmitting unit 120. The power having the required power level has a voltage V_{SC} (effective value) and a current I_{SC} (effective value).

In subsequent step STk, the controller 122 calculates the input voltage Vᵢₙ (effective value) and the input current Iᵢₙ (effective value). Then, in step STm, it is determined whether or not the condition that the input voltage Vᵢₙ is equal to the voltage V_{SC} and the input current Iᵢₙ is equal to the current I_{SC} is satisfied. If the condition is not satisfied in step STm, the step STk is repeated. If the condition is satisfied in step STm, the transmission of the power from the power transmitting unit 120 continues until a stop instruction is given.

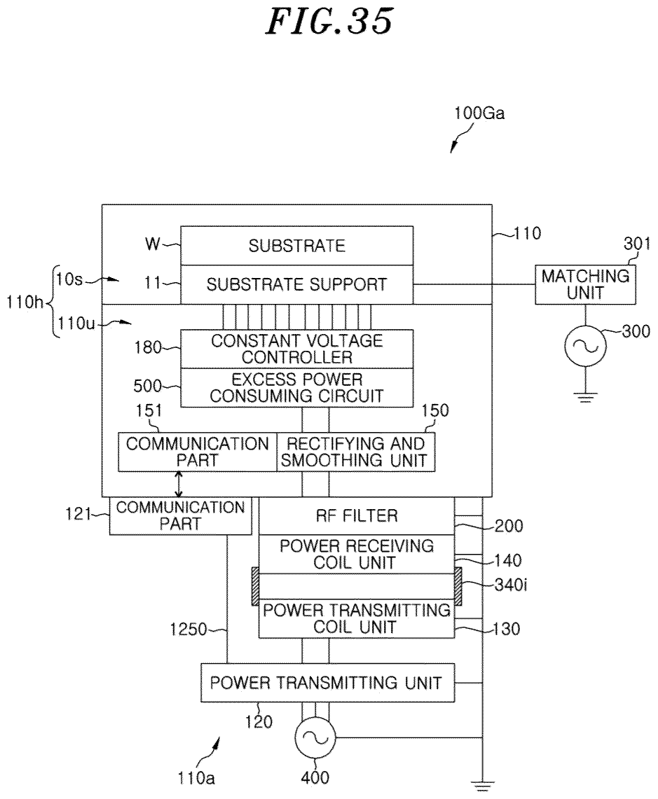

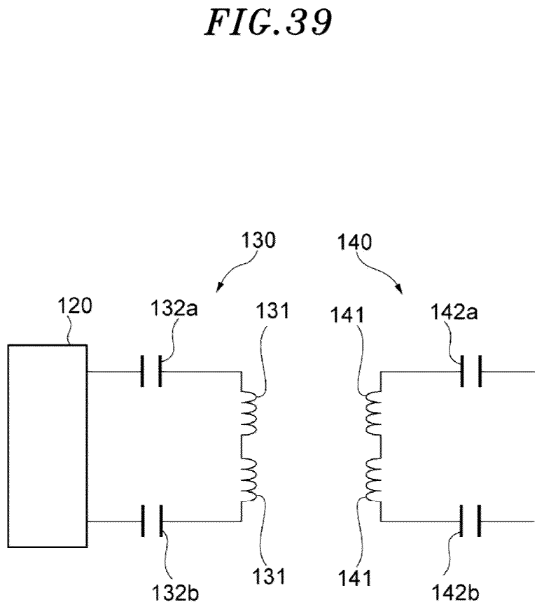

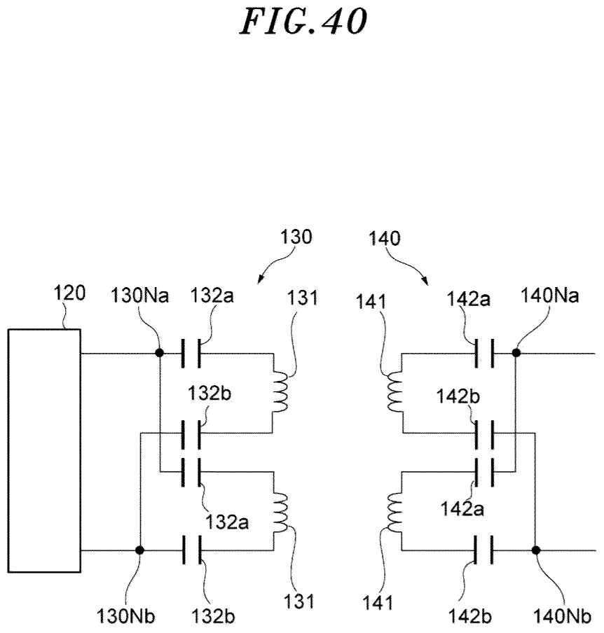

Hereinafter, various modifications of the plasma processing apparatus 100G will be described. FIGS. 35 to 38 and 41 are diagram schematically showing a plasma processing apparatus according to still another exemplary embodiment. FIGS. 39 and 40 are diagrams showing a power transmitting coil unit and a power receiving coil unit in a plasma processing apparatus according to still another exemplary embodiment. Hereinafter, the differences between the exemplary embodiments shown in FIGS. 39 to 41 and the plasma processing apparatus 100G will be described.

In a plasma processing apparatus 100Ga shown in FIG. 35, the power receiving coil unit 140 and the power transmitting coil unit 130 are fixed to each other by a fixing mechanism. The fixing mechanism may include an insulating member 340i. In one example, the insulating member 340i is fixed to the sidewall of the metal housing 130g of the power transmitting coil unit 130 and the sidewall of the metal housing 140g of the power receiving coil unit 140 using a fastening member such as a screw. The screw may be, for example, an insulating resin screw. Accordingly, the relative positional relationship between the power transmitting coil 131 and the power receiving coil 141 is fixed. In the plasma processing apparatus 100Ga, the fixing mechanism improves the accuracy of the relative alignment between the power transmitting coil 131 and the power receiving coil 141. As a result, the power supply efficiency is improved.

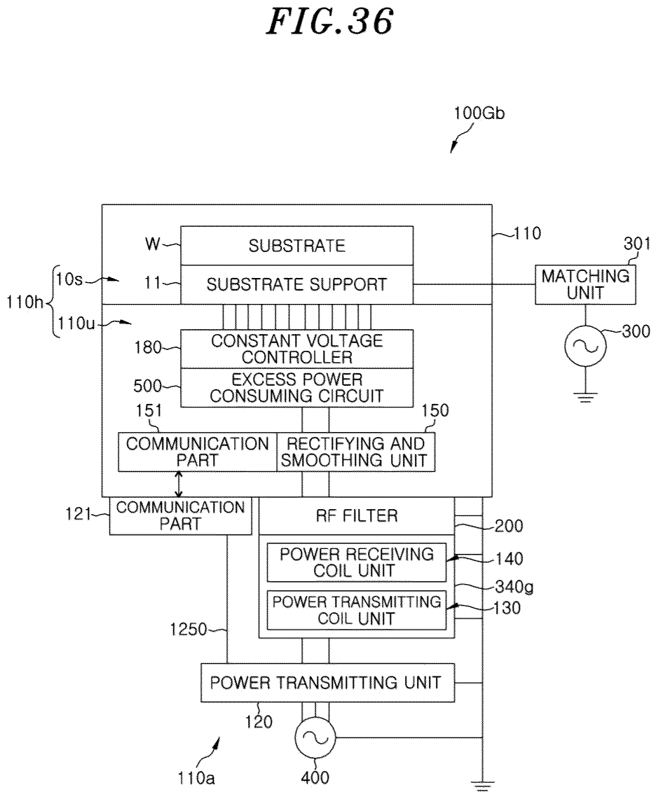

In a plasma processing apparatus 100Gb shown in FIG. 36, the power transmitting coil unit 130 and the power receiving coil unit 140 are integrated. Specifically, the power transmitting coil 131 and the power receiving coil 141 are accommodated in a single metal housing 340g. In one embodiment, a resonant capacitor of the power transmitting coil unit 130 and a resonant capacitor of the power receiving coil unit 140 may be further accommodated in the metal housing 340g. In the plasma processing apparatus 100Gb, the metal housing 340g suppresses the leakage of RF noise to the outside.

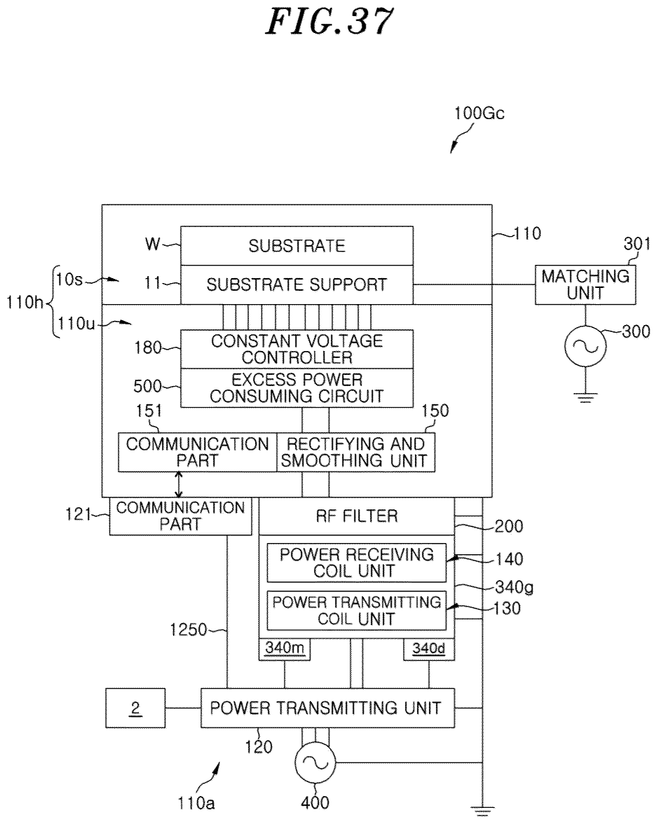

A plasma processing apparatus 100Gc shown in FIG. 37 is different from the plasma processing apparatus 100Gb in that the distance (gap length) between the power transmitting coil 131 and the power receiving coil 141 is variable. Specifically, the plasma processing apparatus 100Gc further includes a driving system 340d and a sensor 340m.

The driving system 340d is configured to move at least one of the power transmitting coil 131 and the power receiving coil 141 to change the distance (gap length) between the power transmitting coil 131 and the power receiving coil 141. In one embodiment, the driving system 340d may move the power transmitting coil 131.

The driving system 340d includes at least one actuator. The at least one actuator includes a hydraulic or pneumatic cylinder, a motor, a piezoelectric element, or the like. The driving system 340d may include a plurality of actuators. The driving system 340d may detect the parallelism of the power transmitting coil 131 and the power receiving coil 141 using the sensor 340m, and control the at least one actuator based on the detection result of the sensor 340m such that the power transmitting coil 131 and the power receiving coil 141 are maintained to be parallel to each other.

In the plasma processing apparatus 100Gc, the distance between the power transmitting coil 131 and the power receiving coil 141 can be changed, so that the power transmission efficiency between the power transmitting coil 131 and the power receiving coil 141 can be improved.

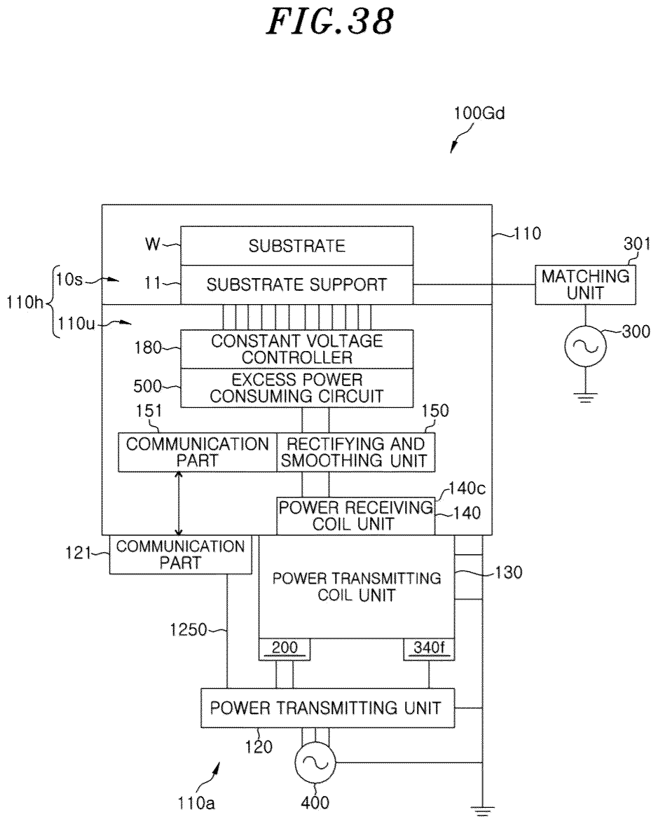

Hereinafter, FIG. 38 will be referred to. As described above, the space 110h includes a space (plasma processing space 10s) in the chamber 10 and a space 110u that is a non-depressurized space. In the plasma processing apparatus 100Gd shown in FIG. 38, the power receiving coil 141 is disposed in the space 110u together with the rectifying and smoothing unit 150 and the power storage unit 160. On the other hand, the power transmitting coil 131 is disposed in the above-described space 110a.

In a plasma processing apparatus 100Gd, a circuit having a high impedance for the frequency of the RF power is provided due to the stray capacitance caused by the space between the power transmitting coil 131 and the power receiving coil 141. Therefore, the leakage of the RF power is suppressed, and the utilization efficiency of the RF power is increased. Hence, if the processing in the plasma processing apparatus 100Gd is etching, a high etching rate can be obtained.

In one embodiment, the power receiving coil 141 may be disposed in the space 110u while being spaced apart from the ground frame 110 by a distance greater than or equal to an insulation distance. In the plasma processing apparatus 100Gd, the potential of the power receiving coil 141 is a potential that is close to the potential of the RF power in the space 110h or the space 110u, and the influence of common node noise, i.e., conductive noise, is reduced depending on the coil distance between the power transmitting coil 131 and the power receiving coil 141. Therefore, as shown in FIG. 38, the power receiving coil 141 and the rectifying and smoothing unit 150 may be directly connected without passing through a filter such as the RF filter 200.

In one embodiment, the power receiving coil unit 140 in the space 110u may have a housing 140c (insulating housing) made of an insulating material. The power receiving coil 141 is accommodated in the housing 140c. The housing 140c extends on the rear side of the power receiving coil 141 with respect to the power transmitting coil 131, and surrounds the outer periphery of the power receiving coil 141.

In one embodiment, the plasma processing apparatus 100Gd may further include a cooling mechanism 340f. The cooling mechanism 340f may be a fan or a blower. The cooling mechanism 340f is configured to cool the power transmitting coil unit 130. The cooling mechanism 340f may be configured to further cool the power receiving coil unit 140.

Further, in the plasma processing apparatus 100Gd, the power transmitting coil unit 130 and the power transmitting unit 120 may be electrically connected to each other via the RF filter 200. In this case, the propagation of conductive noise to the power transmitting unit 120 is further suppressed.

As shown in FIG. 39, in the plasma processing apparatuses according to various exemplary embodiments, the power transmitting coil unit 130 may include two or more power transmitting coils 131 connected in series. Further, the power receiving coil unit 140 may include two or more power receiving coils 141 connected in series. The two or more power transmitting coils 131 are electromagnetically coupled to the two or more power receiving coils 141.

As shown in FIG. 40, in the plasma processing apparatuses according to various exemplary embodiments, the power transmitting coil unit 130 may include two power transmitting coils 131. Further, the power receiving coil unit 140 may include two power receiving coils 141. A first power transmitting coil of the two power transmitting coils 131 is electromagnetically coupled to a first power receiving coil of the two power receiving coils 141. A second power transmitting coil of the two power transmitting coils 131 is electromagnetically coupled to a second power receiving coil of the two power receiving coils 141.

One end of the first power transmitting coil is connected to the power transmitting unit 120 via one of the two resonant capacitors 132a and a node 130Na. The other end of the first power transmitting coil is connected to the power transmitting unit 120 via one of the two resonant capacitors 132b and a node 130Nb. One end of the second power transmitting coil is connected to the power transmitting unit 120 via the other of the two resonant capacitors 132a and a node 130Na. The other end of the second power transmitting coil is connected to the power transmitting unit 120 via the other of the two resonant capacitors 132b and a node 130Nb.

One end of the first power receiving coil is connected to the rectifying and smoothing unit 150 via one of the two resonant capacitors 142a and a node 140Na. The other end of the first power receiving coil is connected to the rectifying and smoothing unit 150 via one of the two resonant capacitors 142b and a node 140Nb. One end of the second power receiving coil is connected to the rectifying and smoothing unit 150 via the other of the two resonant capacitors 142a and a node 140Na. The other end of the second power receiving coil is connected to the rectifying and smoothing unit 150 via the other of the two resonant capacitors 142b and a node 140Nb.

Further, the single resonant capacitor 132a may be connected between the node 130Na and the power transmitting unit 120. The single resonant capacitor 132b may be connected between the node 130Nb and the power transmitting unit 120. In this case, one end of the first power transmitting coil is connected to the power transmitting unit 120 via the node 130Na and the single resonant capacitor 132a, and the other end of the first power transmitting coil is connected to the power transmitting unit 120 via the node 130Nb and the single resonant capacitor 132b. Further, one end of the second power transmitting coil is connected to the power transmitting unit 120 via the node 130Na and the single resonant capacitor 132a, and the other end of the second power transmitting coil is connected to the power transmitting unit 120 via the node 130Nb and the single resonant capacitor 132b.

Further, the single resonant capacitor 142a may be connected between the node 140Na and the rectifying and smoothing unit 150. Further, the single resonant capacitor 142b may be connected between the node 140Nb and the rectifying and smoothing unit 150. In this case, one end of the first receiving coil is connected to the rectifying and smoothing unit 150 via the node 140Na and the single resonant capacitor 142a, and the other end of the first receiving coil is connected to the rectifying and smoothing unit 150 via the node 140Nb and the single resonant capacitor 142b. Further, one end of the second receiving coil is connected to the rectifying and smoothing unit 150 via the node 140Na and the single resonant capacitor 142a, and the other end of the second receiving coil is connected to the rectifying and smoothing unit 150 via the node 140Nb and the single resonant capacitor 142b.

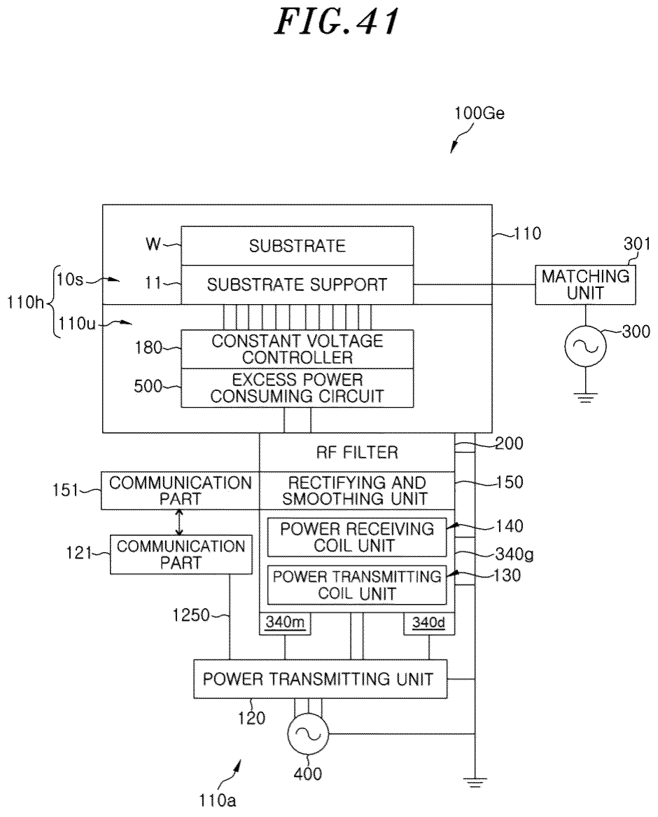

A plasma processing apparatus 100Ge shown in FIG. 41 is different from the plasma processing apparatus 100Gc in that the rectifying and smoothing unit 150 is disposed in the space 110a. The rectifying and smoothing unit 150 may be connected between the power receiving coil unit 140 and the RF filter 200. Further, the RF filter 200 may be omitted. In this case, the rectifying and smoothing unit 150 is connected to the constant voltage controller 180 without passing through the RF filter 200.

### (Plasma Processing Apparatus Including Immittance Converter)

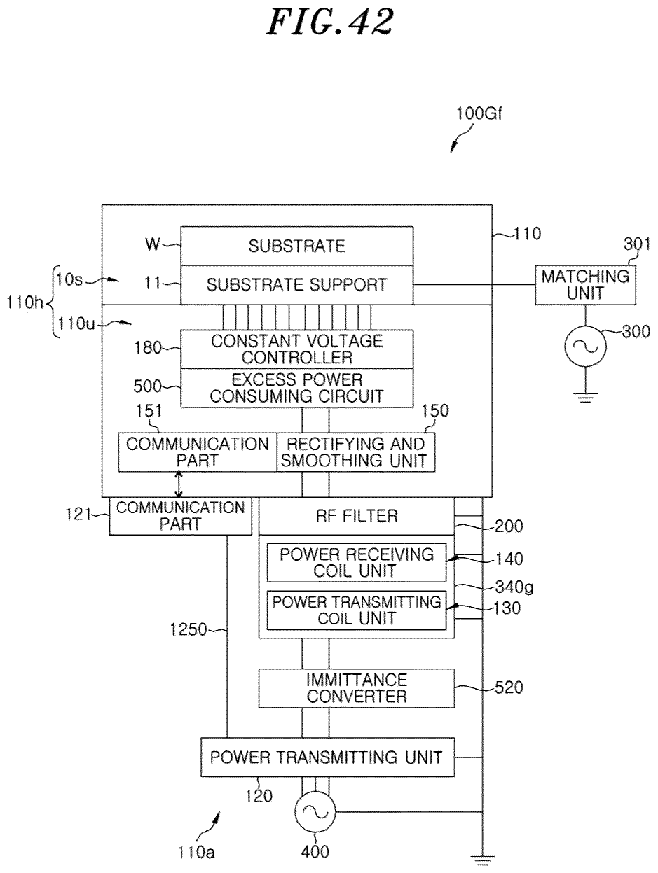

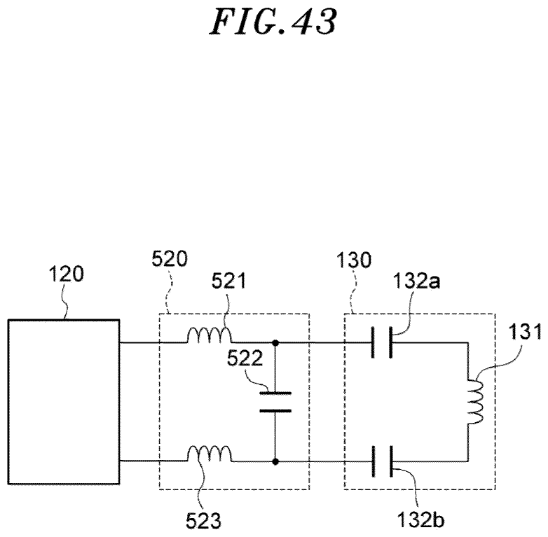

Hereinafter, FIGS. 42 and 43 will be referred to. FIG. 42 is a diagram schematically showing a plasma processing apparatus according to still another exemplary embodiment. FIG. 43 is a diagram showing an immittance converter in a plasma processing apparatus according to still another exemplary embodiment. The plasma processing apparatus of various exemplary embodiments not including the power storage unit 160 may further include an immittance converter 520. The immittance converter 520 includes an immittance conversion circuit connected between the power transmitting unit 120 and the power transmitting coil unit 130. Hereinafter, the differences between the plasma processing apparatus 100Gf shown in FIG. 42 and the plasma processing apparatus 100Gb will be described from the perspective of their distinguishing features.

Referring to FIGS. 42 and 43, the plasma processing apparatus 100Gf further includes the immittance converter 520. The immittance conversion circuit of the immittance converter 520 includes an inductor 521, a capacitor 522, and an inductor 523.

A pair of power supply lines of the immittance conversion circuit, which connect the power transmitting unit 120 and the power transmitting coil unit 130 to each other, may include the same components and have the same line length in order to suppress the phase difference and the potential difference of the conduction noise therebetween. Therefore, the pair of power supply lines includes an inductor 521 and an inductor 523, respectively. In other words, the inductor 521 is connected between the power transmitting unit 120 and one end of the power transmitting coil 131. The inductor 523 is connected between the power transmitting unit 120 and the other end of the power transmitting coil 131. The resonant capacitor 132a may be connected between the inductor 521 and one end of the power transmitting coil 131. Further, the resonant capacitor 132b may be connected between the inductor 523 and the other end of the power transmitting coil 131. Each of the inductor 521 and the inductor 523 may be a coil formed by winding a Litz wire in order to suppress a decrease in the power supply efficiency. Each of the inductors 521 and 523 may be selected to have a withstand voltage against the sum of the transmission voltage and the conductive noise, and to have an allowable current greater than or equal to the transmission current. Further, the inductor 523 may be omitted. In this case, the other end of the power transmitting coil 131 (or the resonant capacitor 132b) is connected to the power transmitting unit 120 without passing through the inductor 523.

The capacitor 522 is connected between a node on a power supply line that connects the inductor 521 and one end of the power transmitting coil 131 (or the resonant capacitor 132a) to each other and a node on a power supply line that connects the inductor 523 and the other end of the power transmitting coil 131 (or the resonant capacitor 132b) to each other. The capacitor 522 may include one or more capacitors. The capacitor 522 may have a capacitance selected to form a resonant circuit together with the power transmitting coil unit 130. Each of the one or more capacitors constituting the capacitor 522 may be a film capacitor or a ceramic capacitor (e.g., a multilayer ceramic capacitor) that does not have a polarity. In addition, each of the one or more capacitors constituting the capacitor 522 may be selected to have a withstand voltage against the sum of the transmission voltage and the conductive noise, and to have an allowable current greater than or equal to the transmission current.

The immittance converter 520 provides a constant current source together with the power transmitting unit 120, so that a constant current is supplied to the power transmitting coil 131 and a constant voltage is supplied to the load. Therefore, in the immittance converter 520, it is possible to perform constant voltage control on the load in response to a wide range of load variation even in a configuration that does not include the power storage unit 160.

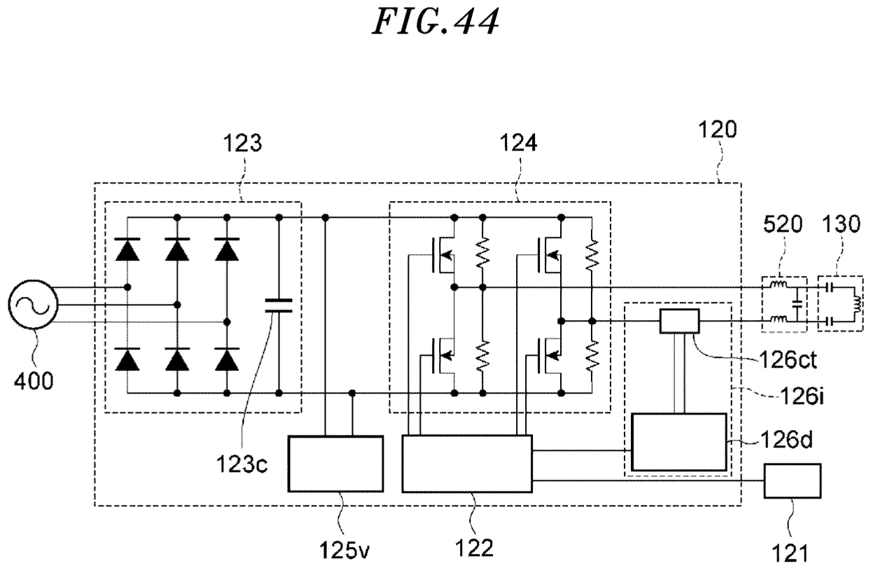

Hereinafter, FIG. 44 will be referred to. FIG. 44 is a diagram showing a power transmitting unit that can be employed in plasma processing apparatuses according to various exemplary embodiments. As shown in FIG. 44, the rectifying and smoothing unit 123 of the power transmitting unit 120 has a rectifying circuit that is a diode bridge and a smoothing circuit that includes a smoothing capacitor 123c. The current detector 126i may include a current transformer 126ct and a transmission current monitoring part 126d. The transmission current monitoring part 126d is configured to monitor the transmission current by monitoring the current outputted from the current transformer 126ct.

In one embodiment, the smoothing capacitor 123c may have a large capacitance to reduce ripples of the transmission power by reducing ripples of the transmission voltage. For example, the smoothing capacitor 123c may have a capacitance of 0.1 mF or more, 0.5 mF or more, or 1 mF or more.

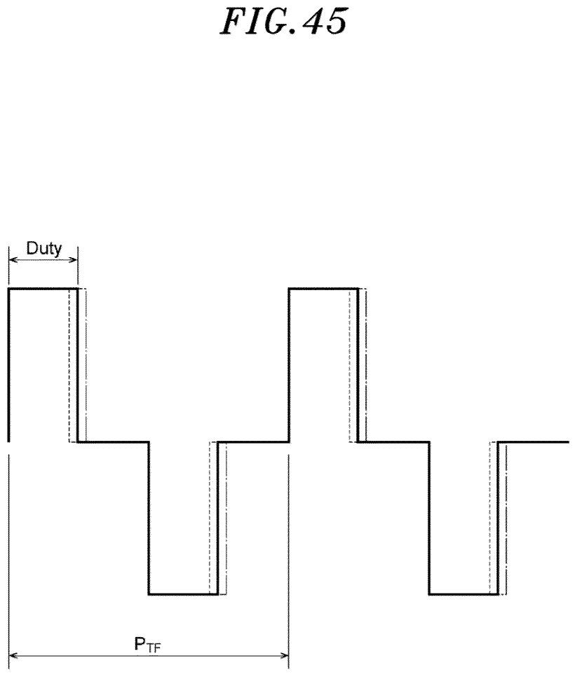

Hereinafter, FIG. 45 will be referred to together with FIG. 44. FIG. 45 is a diagram for explaining adjustment of the duty of the transmission voltage of the power transmitting unit that can be employed in the plasma processing apparatuses according to various exemplary embodiments. In FIG. 45, the waveforms of the transmission voltage that can be transmitted from the power transmitting unit 120 are indicated by a solid line, a dashed line, and a dashed dotted line. In FIG. 45, a period P_{TF} indicates the period of the transmission voltage having a time length that is the reciprocal of the transmission frequency, and Duty indicates the duty of the transmission voltage.

In one embodiment, the controller 122 of the power transmitting unit 120 may adjust the duty of the transmission voltage by controlling the inverter 124 to reduce the ripples of the transmission power outputted from the power transmitting unit 120 even if the output voltage of the rectifying and smoothing unit 123 includes ripples. Specifically, the controller 122 sets the duty (see the dashed line in FIG. 45) of the transmission voltage at the peak of the ripples to a value less than the duty (see the solid line in FIG. 45) of the transmission voltage at the intermediate value of the ripples in accordance with the voltage detected by the voltage detector 125v. Further, the controller 122 sets the duty (see the dashed line in FIG. 45) of the transmission voltage at the trough of the ripples to a value greater than the duty of the transmission voltage at the intermediate value of the ripples in accordance with the voltage detected by the voltage detector 125v.

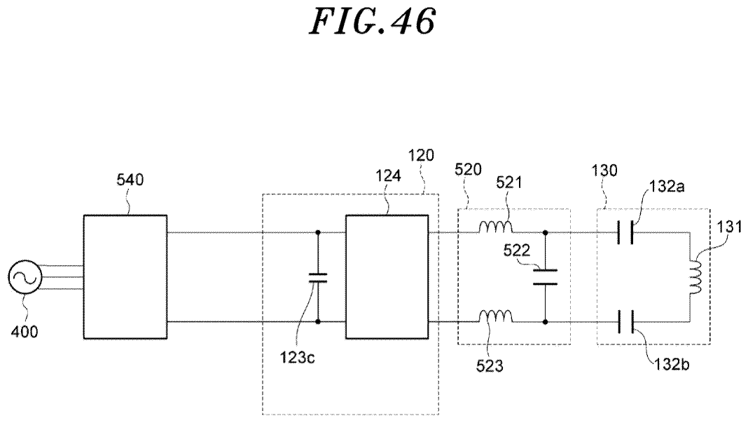

Hereinafter, FIG. 46 will be referred to. FIG. 46 is a diagram showing a power transmitting unit and an AC/DC converter that can be employed in plasma processing apparatuses according to various exemplary embodiments. In the embodiment shown in FIG. 46, the power transmitting unit 120 does not include the rectifying and smoothing unit 123, but includes a smoothing capacitor 123c that constitutes the above-described smoothing circuit. In other words, the power transmitting unit 120 does not include the above-described rectifying circuit (e.g., a diode bridge). In addition, in the embodiment shown in FIG. 46, an AC/DC converter 540 is connected between the AC power supply 400 and the power transmitting unit 120. The AC/DC converter 540 may be a power supply equipped with a power factor correction (PFC) circuit. The PFC circuit can suppress a decrease in the power supply efficiency. In the AC/DC converter 540, the ripples of the output voltage and the output power from the AC/DC converter 540 are reduced, so that the ripples of the transmission voltage outputted from the power transmitting unit 120 are reduced, and the ripples of the transmission power are reduced. Further, since the power transmitting unit 120 does not include a smoothing circuit, the power transmitting unit 120 can be scaled down.

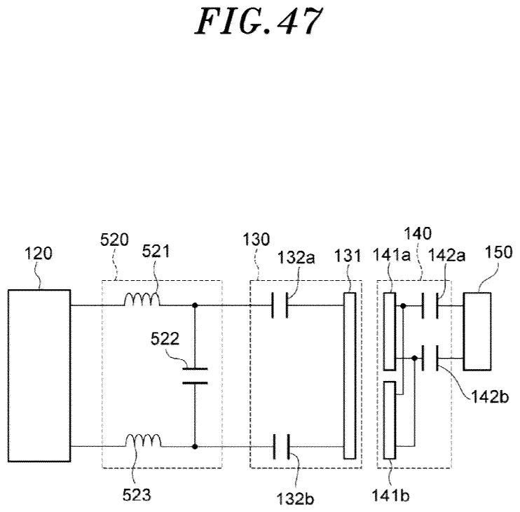

FIG. 47 is a diagram showing a power receiving coil unit 140 that can be employed in plasma processing apparatuses according to various exemplary embodiments. In the example shown in FIG. 47, the power receiving coil unit 140 includes power receiving coils 141a and 141b. One end of the power receiving coil 141a and one end of the power receiving coil 141b are connected to the rectifying and smoothing unit 150 via the resonant capacitor 142a. The other end of the power receiving coil 141a and the other end of the power receiving coil 141b are connected to the rectifying and smoothing unit 150 via the resonant capacitor 142b. As in the example shown in FIG. 47, two or more power receiving coils may be connected in parallel in the power receiving coil unit 140. Accordingly, the allowable current of the power receiving coil in the power receiving coil unit 140 increases.

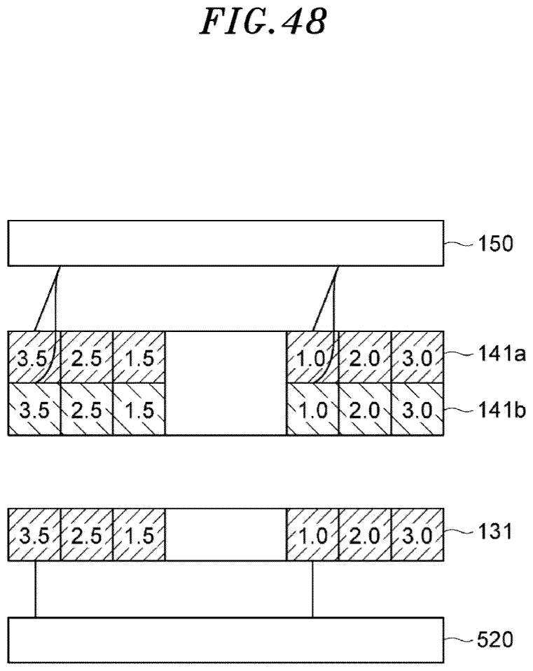

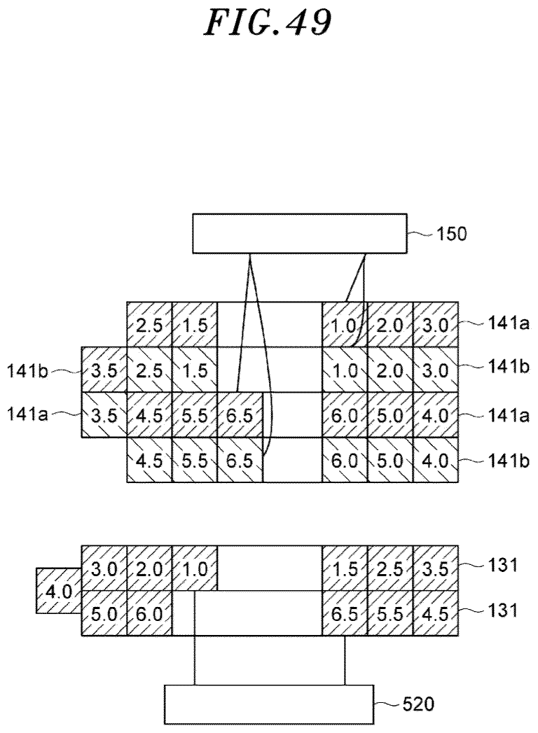

FIGS. 48 and 49 are diagrams showing configurations of a receiving coil and a transmitting coil that can be employed in plasma processing apparatuses according to various exemplary embodiments. In FIG. 48 and FIG. 49, the first digit shown in the rectangle showing the wire of each of the power receiving coil and the power transmitting coil indicates the number of turns in the coil. Further, the number of the first decimal place shown in the rectangle indicates that the wire of the coil is wound from the position “0” to the position “5”. The configuration examples shown in FIG. 48 and FIG. 49 are employed in the power receiving coil unit 140 in which two receiving coils are connected in parallel as in the example shown in FIG. 47.

As shown in FIG. 48, the power receiving coil 141a and the power receiving coil 141b may be arranged such that one of the power receiving coil 141a and the power receiving coil 141b is located between the other of the power receiving coil 141a and the power receiving coil 141b and the power transmitting coil 131. The power receiving coil 141a and the power receiving coil 141b may be made of the same wire material, or may be made of different wire materials. Further, in the example shown in FIG. 48, the rectifying and smoothing unit 150 is connected to the first turn on the innermost side and the last turn on the outermost side (e.g., the third turn) of each of the power receiving coil 141a and the power receiving coil 141b. In addition, the immittance converter 520 is connected to the first turn on the innermost side and the last turn on the outermost side (e.g., the third turn) of each of the power transmitting coils 131.

As shown in FIG. 49, the plurality of turns of each of the power receiving coil 141a and the power receiving coil 141b may be arranged in multiple stages (for example, in two stages). Further, the multiple stages of the power receiving coil 141a and the multiple stages of the power receiving coil 141b may be arranged alternately in the direction in which the multiple stages are arranged. Also in the example shown in FIG. 49, the power receiving coil 141a and the power receiving coil 141b may be made of the same wire material or different wire materials. The multiple turns of the power transmitting coil 131 may also be arranged in multiple stages (for example, in two stages). Further, in the example shown in FIG. 49, the rectifying and smoothing unit 150 is connected to the first turn and the last turn (for example, the sixth turn) on the innermost side of each of the power receiving coil 141a and the power receiving coil 141b. Further, the immittance converter 520 is connected to the first turn and the last turn (for example, the sixth turn) on the innermost side of each of the power transmitting coil 131. In this case, the phase difference and the potential difference of the conductive noise propagating through the lead wires from each of the power receiving coil 141a, the power receiving coil 141b, and the power transmitting coil 131 is reduced.

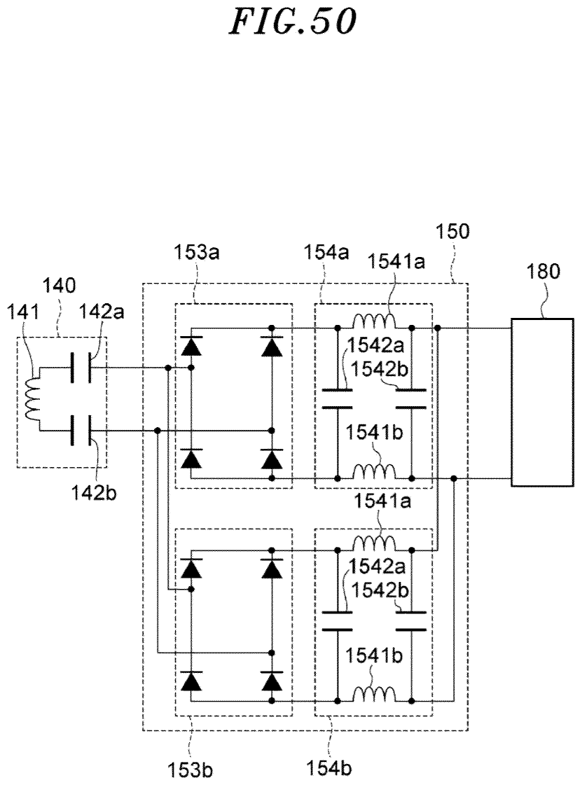

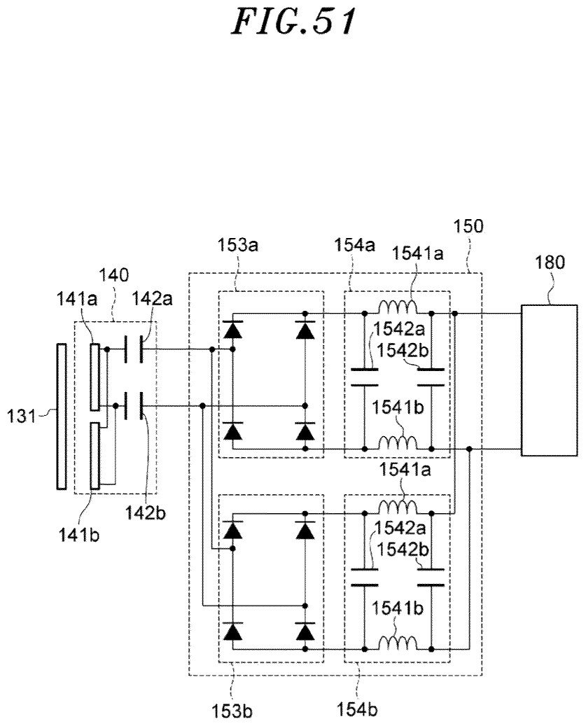

Hereinafter, FIGS. 50 and 51 will be referred to. FIGS. 50 and 51 are diagrams showing configurations of a receiving coil unit and a rectifying and smoothing unit that can be employed in plasma processing apparatuses according to various exemplary embodiments. In the embodiment of FIG. 50, the power receiving coil unit 140 includes a single receiving coil 141. In the embodiment of FIG. 51, the power receiving coil unit 140 includes a plurality of receiving coils connected in parallel, for example, the receiving coil 141a and the receiving coil 141b connected in parallel.

In each of the embodiments shown in FIGS. 50 and 51, the rectifying and smoothing unit 150 includes a rectifying circuit 153a and a rectifying circuit 153b that are similar to the rectifying circuit 153, and includes a smoothing circuit 154a and a smoothing circuit 154b that are similar to the smoothing circuit 154. The rectifying circuit 153a is connected to the smoothing circuit 154a, and the rectifying circuit 153b is connected to the smoothing circuit 154b. In the rectifying and smoothing unit 150 in each of the embodiments shown in FIGS. 50 and 51, the rectifying circuit 153b and the smoothing circuit 154b are connected in parallel to the rectifying circuit 153a and the smoothing circuit 154a.

In the embodiment of FIG. 50, one end of the power receiving coil 141 is connected to the rectifying circuit 153a and the rectifying circuit 153b via the resonant capacitor 142a. The other end of the power receiving coil 141 is connected to the rectifying circuit 153a and the rectifying circuit 153b via the resonant capacitor 142b. In the embodiment of FIG. 51, one end of the power receiving coil 141a and one end of the power receiving coil 141b are connected to the rectifying circuit 153a and the rectifying circuit 153b via the resonant capacitor 142a. The other end of the power receiving coil 141a and the other end of the power receiving coil 141b are connected to the rectifying circuit 153a and the rectifying circuit 153b via the resonant capacitor 142b.

In each of the embodiments shown in FIGS. 50 and 51, each of the smoothing circuits 154a and 154b includes an inductor 1541a, an inductor 1541b, a capacitor 1542a, and a capacitor 1542b. The inductor 1541a is connected between one of a pair of inputs of the smoothing circuit 154a or 154b and one of a pair of outputs of the smoothing circuit. The inductor 1541b is connected between the other of the pair of inputs of the smoothing circuit 154a or 154b and the other of a pair of outputs of the smoothing circuit. By providing an inductor in each of the pair of power supply lines of the smoothing circuit 154a and the smoothing circuit 154b, the phase difference and the potential difference of the conduction noise between the pair of power supply lines are suppressed. Further, the smoothing circuit 154 shown in FIG. 14 may further include an inductor 1541b, similarly to the smoothing circuit 154a and the smoothing circuit 154b.

In each of the embodiments shown in FIG. 50 and FIG. 51, one end of the capacitor 1542a is connected to one of the pair of inputs of the smoothing circuit 154a or 154b and one end of the inductor 1541a. The other end of the capacitor 1542a is connected to the other of the pair of inputs of the smoothing circuit 154a or 154b and one end of the inductor 1541b. One end of the capacitor 1542b is connected to one of the pair of outputs of the smoothing circuit 154a or 154b and the other end of the inductor 1541a. The other end of the capacitor 1542b is connected to the other of the pair of outputs of the smoothing circuit 154a or 154b and the other end of the inductor 1541b.

In each of the embodiments shown in FIGS. 50 and 51, the allowable current is increased by parallelizing the unit including the rectifying circuit and the parallel circuit. Further, the inductance of the inductor 1541a and the inductor 1541b may be equal to each other, or may be different from each other. Further, the capacitance of the capacitor 1542a of the smoothing circuit 154a, the capacitance of the capacitor 1542b of the smoothing circuit 154a, the capacitance of the capacitor 1542a of the smoothing circuit 154b, and the capacitance of the capacitor 1542b of the smoothing circuit 154b may be equal to each other, or may be different from each other. Further, each of the smoothing circuits 154a and 154b may not have the inductor 1541b. Alternatively, the smoothing circuit 154a may not have the inductor 1541b, and the smoothing circuit 154b may not have the inductor 1541a.

### (Integrated Configuration Related to Power Supply)

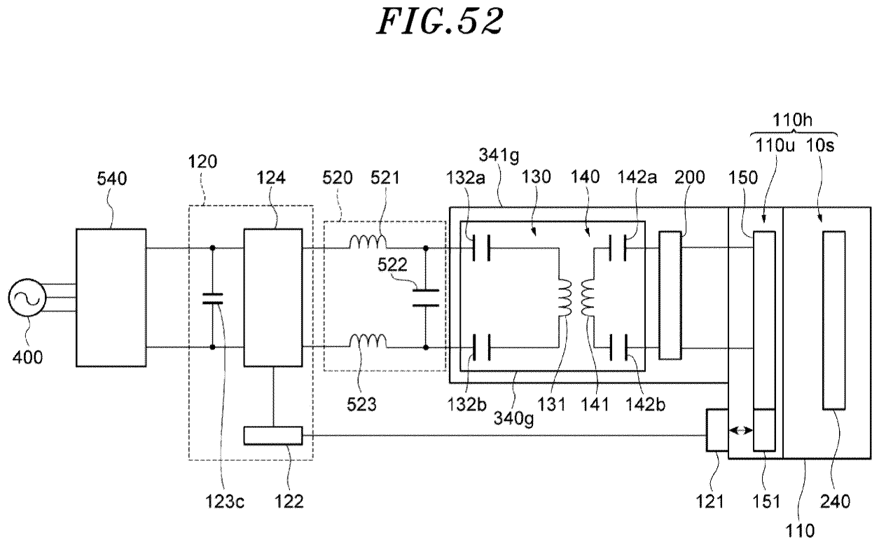

Hereinafter, FIGS. 52 to 56 will be referred to. FIGS. 52 to 56 are diagrams showing an integrated configuration related to the power supply, which can be employed in plasma processing apparatuses according to various exemplary embodiments. Each of the configurations in FIGS. 52 to 56 is employed in the plasma processing apparatus including the immittance converter 520 and the AC/DC converter 540.

In the embodiment shown in FIG. 52, the power transmitting coil unit 130 and the power receiving coil unit 140 are integrated in the single metal housing 340g. Further, the power transmitting coil unit 130, the power receiving coil unit 140, and the RF filter 200 are also integrated in the space 110a. The power transmitting coil unit 130, the power receiving coil unit 140, and the RF filter 200 are arranged in, for example, a single metal housing 341g.

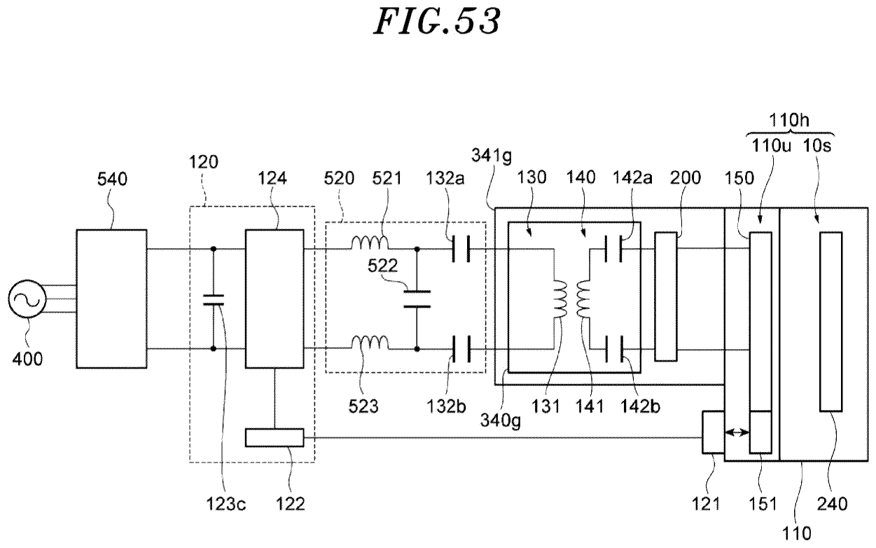

The embodiment shown in FIG. 53 is different from the embodiment shown in FIG. 52 in that the resonant capacitors 132a and 132b of the power transmitting coil unit 130 are integrated with the immittance converter 520. The resonant capacitors 132a and 132b may be disposed in a single housing together with the immittance conversion circuit of the immittance converter 520. In the embodiment in FIG. 53, the unit formed by integrating the power transmitting coil unit 130, the power receiving coil unit 140, and the RF filter 200 can be scaled down.

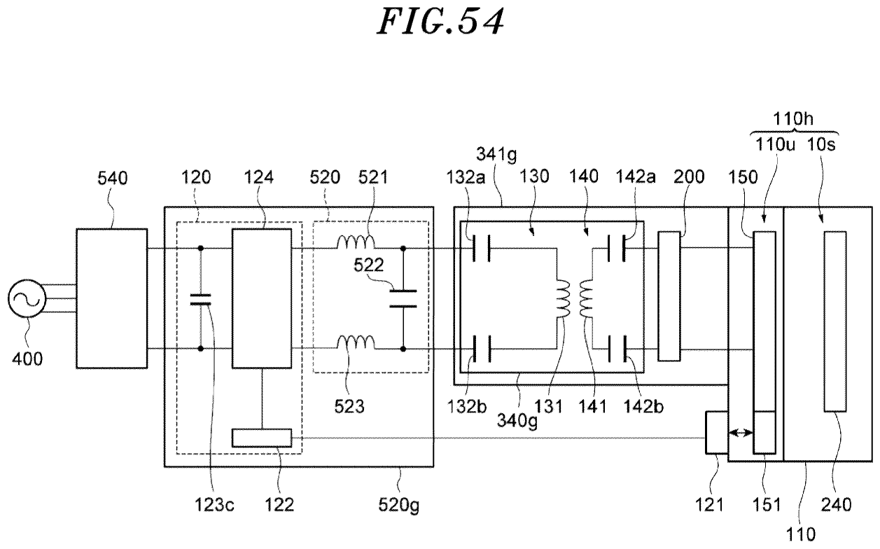

The embodiment shown in FIG. 54 is different from the embodiment shown in FIG. 52 in that the immittance converter 520 and the power transmitting unit 120 are integrated. The immittance converter 520 and the power transmitting unit 120 may be disposed in a single housing 520g. In the present embodiment, the wiring between the inverter of the power transmitting unit 120 and the immittance converter 520 can be shortened. Therefore, the power supply efficiency can be improved.

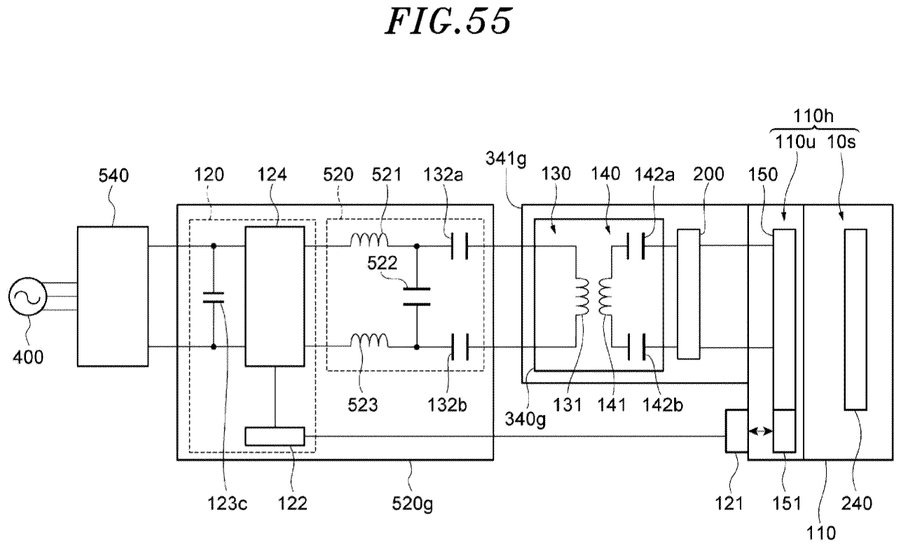

The embodiment shown in FIG. 55 is different from the embodiment shown in FIG. 52 in that the resonant capacitors 132a and 132b of the power transmitting coil unit 130, the immittance converter 520, and the power transmitting unit 120 are integrated. The resonant capacitors 132a and 132b of the power transmitting coil unit 130, the immittance converter 520, and the power transmitting unit 120 may be arranged in the single housing 520g. In the present embodiment, the unit formed by integrating the power transmitting coil unit 130, the power receiving coil unit 140, and the RF filter 200 can be scaled down. In addition, in the present embodiment, the wiring between the inverter of the power transmitting unit 120 and the immittance converter 520 can be shortened. Therefore, the power supply efficiency can be improved.

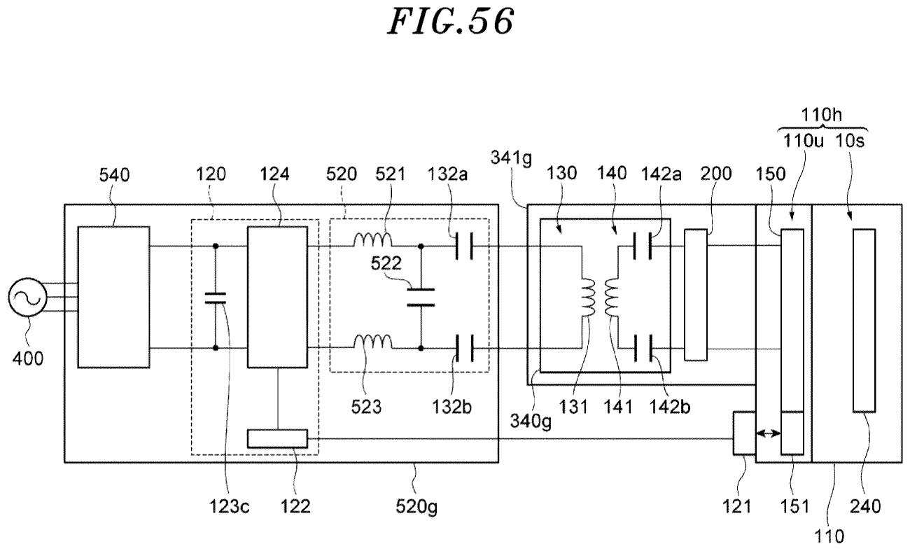

The embodiment shown in FIG. 56 is different from the embodiment shown in FIG. 52 in that the resonant capacitors 132a and 132b of the power transmitting coil unit 130, the immittance converter 520, the power transmitting unit 120, and the AC/DC converter 540 are integrated. The resonant capacitors 132a and 132b of the power transmitting coil unit 130, the immittance converter 520, the power transmitting unit 120, and the AC/DC converter 540 may be arranged in the single housing 520g. In the present embodiment, the unit formed by integrating the power transmitting coil unit 130, the power receiving coil unit 140, and the RF filter 200 can be scaled down. Further, in the present embodiment, the wiring between the inverter of the power transmitting unit 120 and the immittance converter 520 can be shortened. Therefore, the power supply efficiency can be improved. In addition, the degree of freedom of layout between the AC power supply 400 and the AC/DC converter 540 is increased.

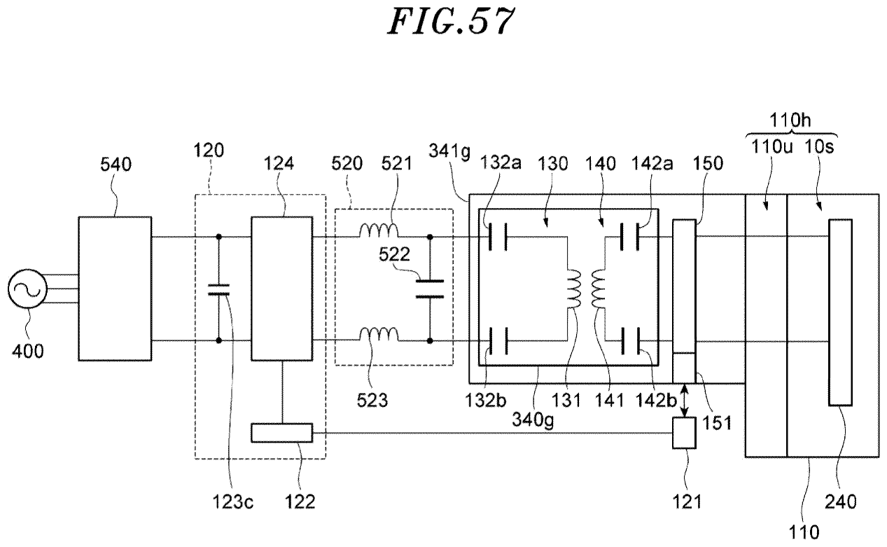

Hereinafter, FIGS. 57 to 61 will be referred to. FIGS. 57 to 61 are diagrams showing an integrated configuration related to the power supply, which can be employed in plasma processing apparatuses according to various exemplary embodiments. Each of the configurations in FIGS. 57 to 61 is employed in the plasma processing apparatus including the immittance converter 520 and the AC/DC converter 540. Unlike the configurations shown in FIGS. 52 to 56, each of the configurations shown in FIGS. 57 to 61 does not include the RF filter 200. Further, in each of the configurations in FIGS. 57 to 61, the rectifying and smoothing unit 150 is disposed in the space 110a.

In the embodiment shown in FIG. 57, the power transmitting coil unit 130 and the power receiving coil unit 140 are integrated in the single metal housing 340g. Further, the power transmitting coil unit 130, the power receiving coil unit 140, and the rectifying and smoothing unit 150 are also integrated in the space 110a. The power transmitting coil unit 130, the power receiving coil unit 140, and the rectifying and smoothing unit 150 are disposed in, for example, the single metal housing 341g.

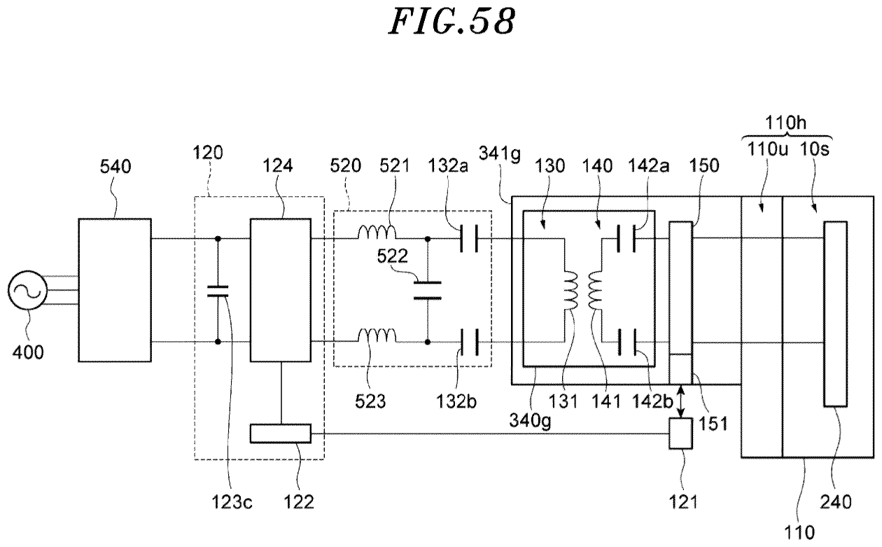

The embodiment shown in FIG. 58 is different from the embodiment shown in FIG. 57 in that the resonant capacitors 132a and 132b of the power transmitting coil unit 130 are integrated with the immittance converter 520. The resonant capacitors 132a and 132b may be disposed in a single housing together with the immittance conversion circuit of the immittance converter 520. In the embodiment shown in FIG. 58, the unit formed by integrating the power transmitting coil unit 130, the power receiving coil unit 140, and the rectifying and smoothing unit 150 can be scaled down.

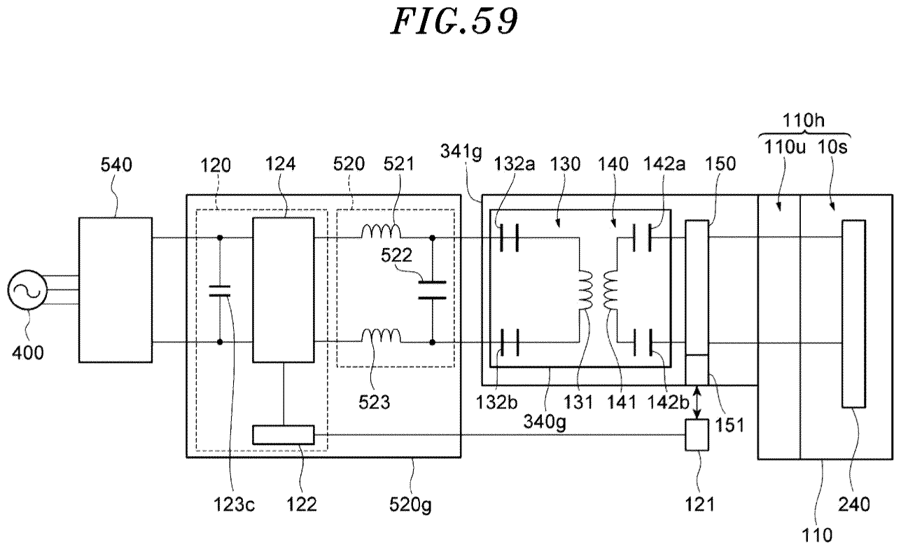

The embodiment shown in FIG. 59 is different from the embodiment shown in FIG. 57 in that the immittance converter 520 and the power transmitting unit 120 are integrated. The immittance converter 520 and the power transmitting unit 120 may be disposed in the single housing 520g. In the present embodiment, the wiring between the inverter of the power transmitting unit 120 and the immittance converter 520 can be shortened. Therefore, the power supply efficiency can be improved.

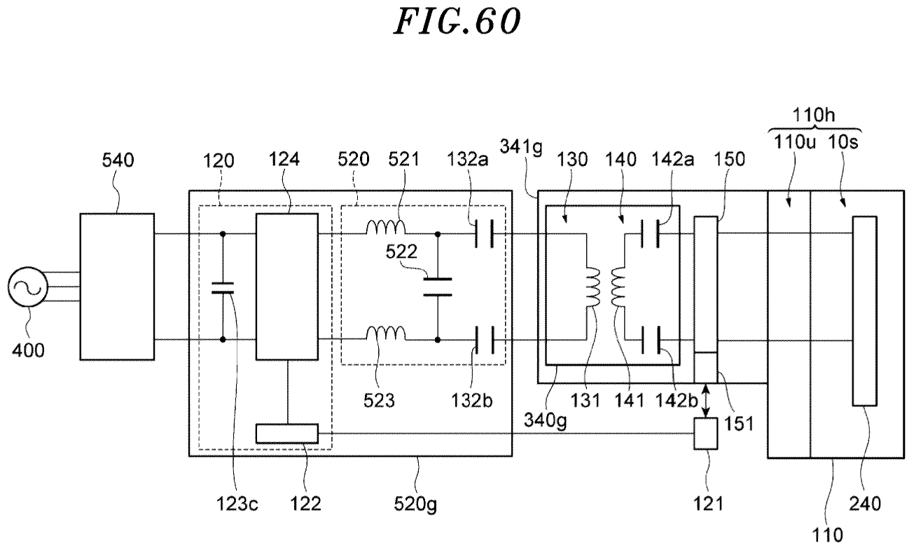

The embodiment shown in FIG. 60 is different from the embodiment shown in FIG. 57 in that the resonant capacitors 132a and 132b of the power transmitting coil unit 130, the immittance converter 520, and the power transmitting unit 120 are integrated. The resonant capacitors 132a and 132b of the power transmitting coil unit 130, the immittance converter 520, and the power transmitting unit 120 may be arranged in the single housing 520g. In the present embodiment, the unit formed by integrating the power transmitting coil unit 130, the power receiving coil unit 140, and the rectifying and smoothing unit 150 can be scaled down. In addition, in the present embodiment, the wiring between the inverter of the power transmitting unit 120 and the immittance converter 520 can be shortened. Therefore, the power supply efficiency can be improved.

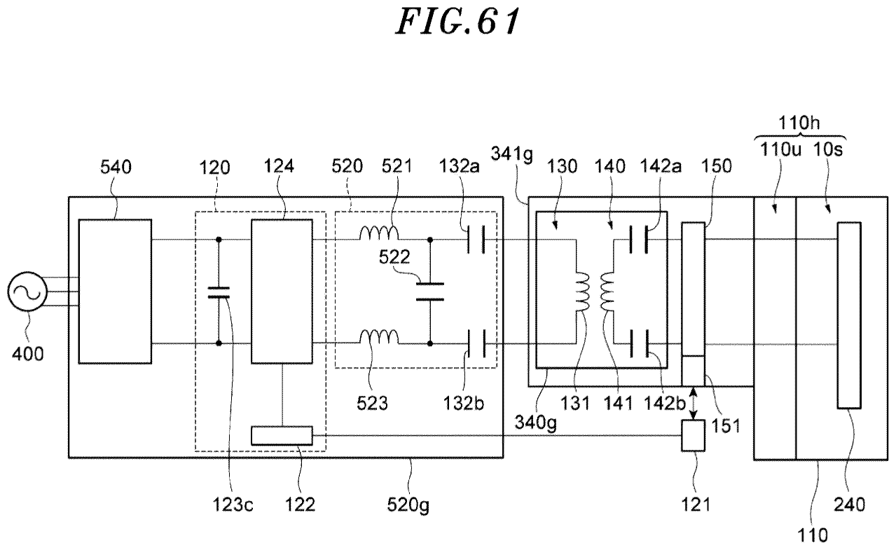

The embodiment shown in FIG. 61 is different from the embodiment shown in FIG. 57 in that the resonant capacitors 132a and 132b of the power transmitting coil unit 130, the immittance converter 520, the power transmitting unit 120, and the AC/DC converter 540 are integrated. The resonant capacitors 132a and 132b of the power transmitting coil unit 130, the immittance converter 520, the power transmitting unit 120, and the AC/DC converter 540 may be arranged in the single housing 520g. In the present embodiment, the unit formed by integrating the power transmitting coil unit 130, the power receiving coil unit 140, and the rectifying and smoothing unit 150 can be scaled down. Further, in the present embodiment, the wiring between the AC/DC converter 540 and the immittance converter 520 can be shortened. Therefore, the power supply efficiency can be improved. In addition, the degree of freedom of layout between the AC power supply 400 and the AC/DC converter 540 is increased.

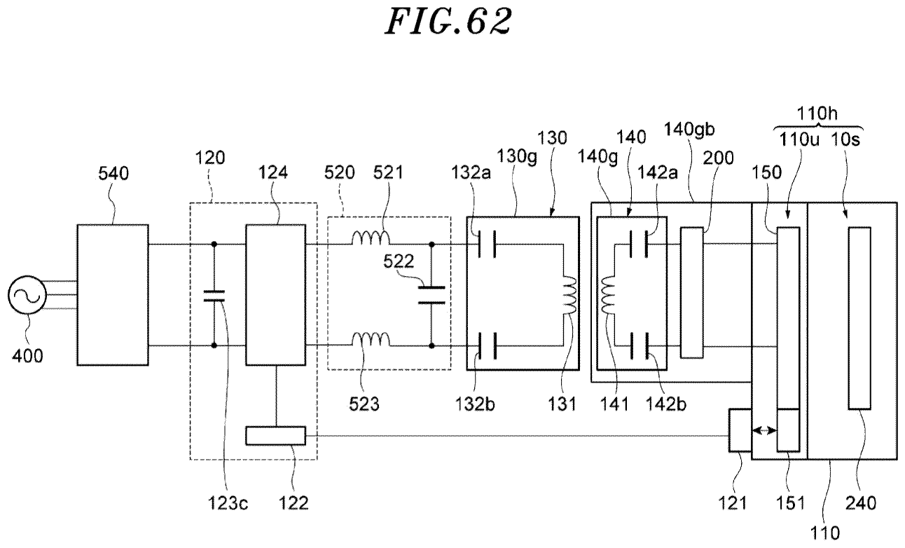

Hereinafter, FIGS. 62 to 65 will be referred to. FIGS. 62 to 65 are diagrams showing an integrated configuration related to the power supply, which can be employed in plasma processing apparatuses according to various exemplary embodiments. Each of the configurations in FIGS. 62 to 65 is employed in the plasma processing apparatus including the immittance converter 520 and the AC/DC converter 540.

In the embodiment shown in FIG. 62, the power receiving coil unit 140 and the RF filter 200 are integrated in the space 110a. The power receiving coil unit 140 and the RF filter 200 are disposed in, for example, a single metal housing 140gb.

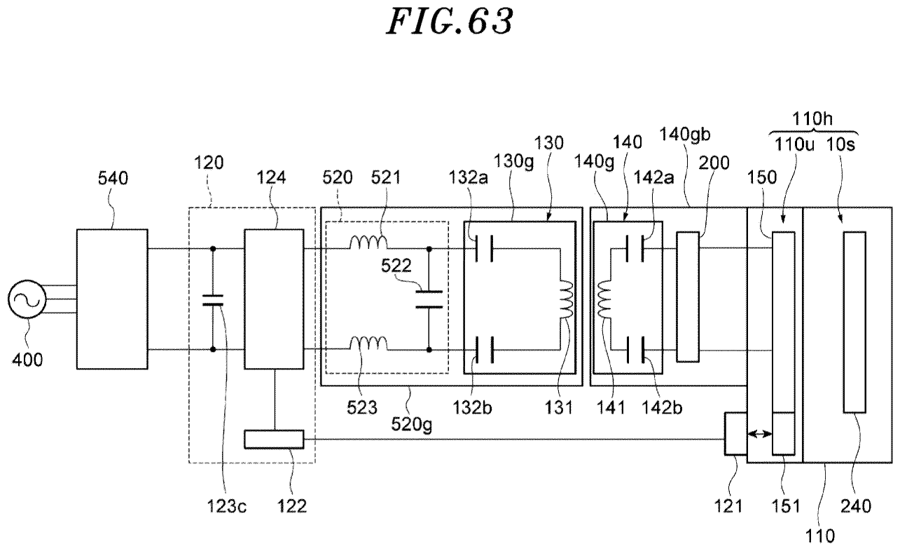

The embodiment shown in FIG. 63 is different from the embodiment in FIG. 62 in that the power transmitting coil unit 130 and the immittance converter 520 are integrated. The power transmitting coil unit 130 and the immittance converter 520 may be disposed in the single housing 520g (e.g., a metal housing) or the metal housing 130g. In the present embodiment, it is possible to shorten the wiring between the immittance converter 520 and the power transmitting coil 131. Therefore, the power supply efficiency can be improved.

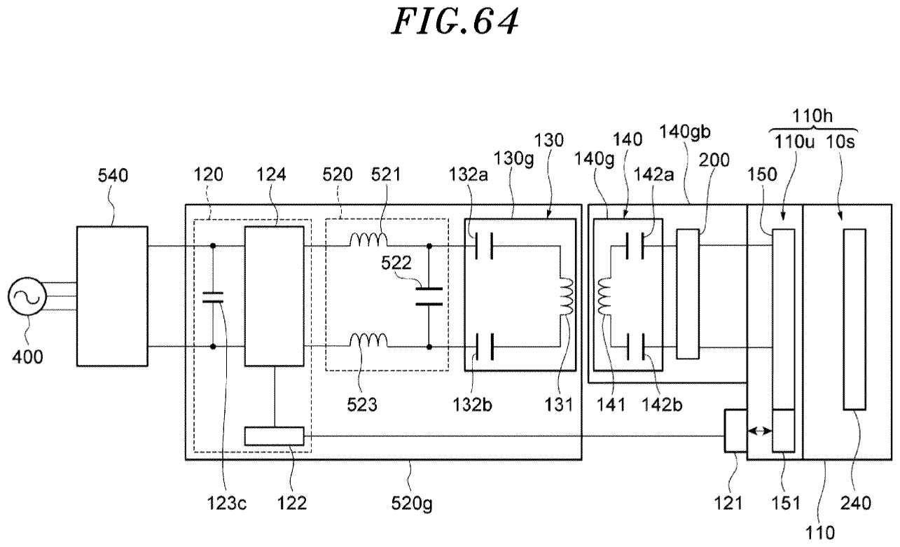

The embodiment shown in FIG. 64 is different from the embodiment in FIG. 62 in that the power transmitting coil unit 130, the immittance converter 520, and the power transmitting unit 120 are integrated. The power transmitting coil unit 130, the immittance converter 520, and the power transmitting unit 120 may be disposed in the single housing 520g (e.g., a metal housing) or the metal housing 130g. In the present embodiment, it is possible to shorten the wiring between the inverter of the power transmitting unit 120 and the power transmitting coil 131. Therefore, the power supply efficiency can be improved.

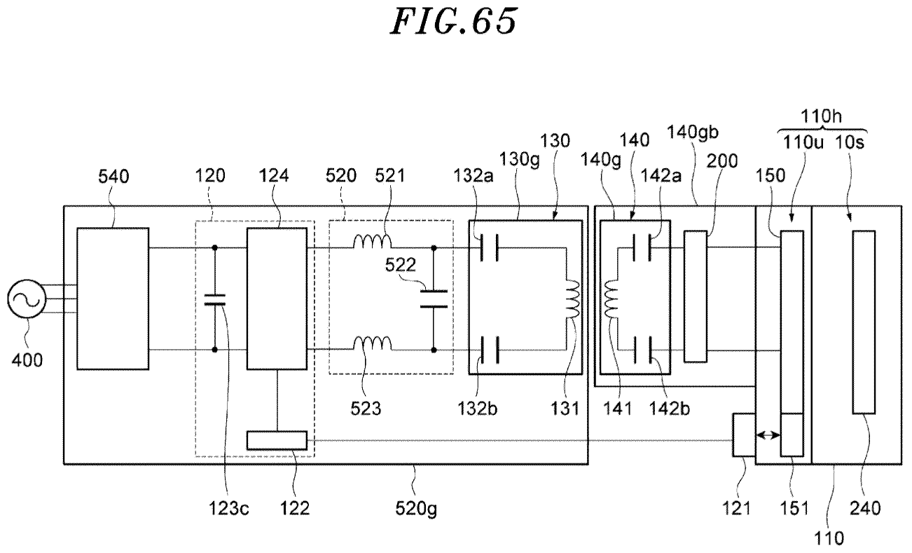

The embodiment shown in FIG. 65 is different from the embodiment in FIG. 62 in that the power transmitting coil unit 130, the immittance converter 520, the power transmitting unit 120, and the AC/DC converter 540 are integrated. The power transmitting coil unit 130, the immittance converter 520, the power transmitting unit 120, and the AC/DC converter 540 may be disposed in the single housing 520g (e.g., a metal housing) or the metal housing 130g. In the present embodiment, it is possible to shorten the wiring between the AC/DC converter 540 and the power transmitting coil 131. Therefore, the power supply efficiency can be improved. In addition, the degree of freedom of the layout between the AC power supply 400 and the AC/DC converter 540 is increased.

While various embodiments have been described above, the present disclosure is not limited to the above-described embodiments, and various additions, omissions, substitutions and changes may be made. Further, other embodiments can be implemented by combining elements in different embodiments.

For example, the AC power supply 400 may be a three-phase AC power supply or a single-phase AC power supply.

Various exemplary embodiments included in the present disclosure will be described in following [E1] to [E17].

### [E1]

A plasma processing apparatus comprising:
a plasma processing chamber;
a substrate support disposed in the plasma processing chamber;
an electrode or an antenna disposed outside a plasma processing space in the plasma processing chamber, the electrode or the antenna being disposed such that a space in the plasma processing chamber is located between the electrode or antenna and the substrate support;
a radio frequency (RF) power supply configured to generate an RF power, and electrically connected to the substrate support, the electrode or the antenna;
at least one power-consuming member disposed in the plasma processing chamber or the substrate support;
a power receiving coil that is electrically connected to said at least one power-consuming member;
a power transmitting coil that is electromagnetically inductively coupled with the power receiving coil;
a power transmitting unit that is electrically connected to the power transmitting coil to supply a power to the power transmitting coil; and
a controller,
wherein the power transmitting unit includes a voltage detector configured to detect an input voltage to the power transmitting coil and a current detector configured to detect an input current to the power transmitting coil, and
the controller is configured to determine a required power level corresponding to a parameter value including an input impedance obtained from the input voltage and the input current or a load resistance value of said at least one power-consuming member, and to control the power transmitting unit to output an output power having the required power level.

### [E2]

The plasma processing apparatus of E1, wherein the power transmitting unit is configured to output a power by outputting an output current having a transmission frequency and periodically outputting an output voltage having a peak value and a duty ratio at a time interval that is the inverse of the transmission frequency, and
the plasma processing apparatus further comprising:
a rectifying and smoothing unit having a rectifying circuit and a smoothing circuit connected between the power receiving coil and said at least one power-consuming member, and
a constant voltage controller configured to change a load resistance value of said at least one power-consuming member and connected between the rectifying and smoothing unit and said at least one power-consuming member.

### [E3]

The plasma processing apparatus of E2, wherein the controller has a table in which a peak value and a duty ratio of the output voltage and an amplitude of the output current corresponding to the parameter value are stored in association with the parameter value, and is configured to cause the power transmitting unit to output the output power having a peak value and a duty ratio of the output voltage and an amplitude value of the output current corresponding to the parameter value.

### [E4]

The plasma processing apparatus of E2 or E3, further comprising:
a line capacitor;
an excess power-consuming load; and
a switching element configured to selectively connect the line capacitor between a pair of power supply lines that connect the rectifying and smoothing unit and the constant voltage controller to each other or to selectively connect the line capacitor to the excess power-consuming load.

### [E5]

The plasma processing apparatus of E4, wherein the constant voltage controller includes a controller configured to change a load resistance value of said at least one power-consuming member, and to control the switching element.

### [E6]

The plasma processing apparatus of E5, wherein the controller of the constant voltage controller is configured to control the switching element to connect the line capacitor to the pair of power supply lines when the load resistance value of said at least one power-consuming component changes to be decreased, and then control the switching element to connect the line capacitor to the excess power-consuming load in order to discharge the power stored in the line capacitor to the excess power-consuming load.

### [E7]

The plasma processing apparatus of any one of E2 to E6, further comprising: an immittance converter including an immittance conversion circuit connected between the power transmitting unit and the power transmitting coil.

### [E8]

The plasma processing apparatus of E7, wherein the immittance conversion circuit includes:
an inductor connected between the power transmitting unit and the power transmitting coil; and
a capacitor connected between a pair of power supply lines that connect the power transmitting unit and the power transmitting coil to each other.

### [E9]

The plasma processing apparatus of E8, wherein the power transmitting unit includes:
a rectifying and smoothing unit including a rectifying circuit and a smoothing capacitor connected between the power transmitting coil and the rectifying circuit;
an inverter connected between the power transmitting coil and the rectifying and smoothing unit of the power transmitting unit;
a voltage monitoring part configured to monitor a waveform of a voltage outputted from the rectifying and smoothing unit of the power transmitting unit; and
and a controller,
wherein the controller is configured to adjust a duty ratio of the output voltage outputted from the inverter in accordance with the waveform monitored by the voltage monitoring part to suppress ripples of the output power.

### [E10]

The plasma processing apparatus of E8, further comprising:
an AC/DC converter,
wherein the power transmitting unit includes:
a smoothing unit including a smoothing capacitor and connected to the AC/DC converter,
an inverter connected between the power transmitting coil and the smoothing unit of the power transmitting unit,
a voltage monitoring part configured to monitor a waveform of a voltage outputted from the smoothing unit of the power transmitting unit, and
a controller,
wherein the controller is configured to adjust the duty ratio of the output voltage outputted from the inverter in accordance with the waveform monitored by the voltage monitoring part to suppress ripples of the output power.

### [E11]

The plasma processing apparatus of any one of E7 to E10, further comprising:
a resonant capacitor connected between the power transmitting coil and the immittance conversion circuit,
wherein the resonant capacitor is provided in the immittance converter.

### [E12]

The plasma processing apparatus of any one of E7 to E10, wherein the immittance converter and the power transmitting unit are accommodated in a single housing.

### [E13]

The plasma processing apparatus of any one of E7 to E10, further comprising:
a resonant capacitor connected between the power transmitting coil and the immittance conversion circuit,
wherein the resonant capacitor, the immittance converter, and the power transmitting unit are accommodated in a single housing.

### [E14]

The plasma processing apparatus of any one of E7 to E10, further comprising:
a power transmitting coil unit including the power transmitting coil and a resonant capacitor connected between the power transmitting coil and the immittance conversion circuit,
wherein the power transmitting coil unit and the immittance converter are accommodated in a single housing.

### [E15]

The plasma processing apparatus of any one of E7 to E10, further comprising:
a power transmitting coil unit including the power transmitting coil and a resonant capacitor connected between the power transmitting coil and the immittance conversion circuit,
wherein the power transmitting coil unit, the immittance converter, and the power transmitting unit are accommodated in a single housing.

### [E16]

The plasma processing apparatus of E10, further comprising:
a resonant capacitor connected between the power transmitting coil and the immittance conversion circuit,
wherein the resonant capacitor, the AC/DC converter, the immittance converter, and the power transmitting unit are accommodated in a single housing.

### [E17]

The plasma processing apparatus of E10, further comprising:
a power transmitting coil unit including the power transmitting coil and a resonant capacitor connected between the power transmitting coil and the immittance conversion circuit,
wherein the power transmitting coil unit, the AC/DC converter, the immittance converter, and the power transmitting unit are housed in a single housing.

From the above description, it will be appreciated that various embodiments of the present disclosure have been described herein for purposes of illustration, and that various changes can be made without departing from the scope and spirit of the present disclosure. Therefore, the various embodiments disclosed herein are not intended to be limiting, with a true scope and spirit being indicated by the appended claims.

1. A plasma processing apparatus comprising:
a plasma processing chamber;
a substrate support disposed in the plasma processing chamber;
an electrode or an antenna disposed outside a plasma processing space in the plasma processing chamber, the electrode or the antenna being disposed such that a space in the plasma processing chamber is located between the electrode or antenna and the substrate support;
a radio frequency (RF) power supply configured to generate an RF power, and electrically connected to the substrate support, the electrode or the antenna;
at least one power-consuming member disposed in the plasma processing chamber or the substrate support;
a power receiving coil that is electrically connected to said at least one power-consuming member;
a power transmitting coil that is electromagnetically inductively coupled with the power receiving coil;
a power transmitting unit that is electrically connected to the power transmitting coil to supply a power to the power transmitting coil; and
a controller,
wherein the power transmitting unit includes a voltage detector configured to detect an input voltage to the power transmitting coil and a current detector configured to detect an input current to the power transmitting coil, and
the controller is configured to determine a required power level corresponding to a parameter value including an input impedance obtained from the input voltage and the input current or a load resistance value of said at least one power-consuming member, and to control the power transmitting unit to output an output power having the required power level.

2. The plasma processing apparatus of claim 1, wherein the power transmitting unit is configured to output a power by outputting an output current having a transmission frequency and periodically outputting an output voltage having a peak value and a duty ratio at a time interval that is the inverse of the transmission frequency, and
the plasma processing apparatus further comprising:
a rectifying and smoothing unit having a rectifying circuit and a smoothing circuit connected between the power receiving coil and said at least one power-consuming member, and
a constant voltage controller configured to change a load resistance value of said at least one power-consuming member and connected between the rectifying and smoothing unit and said at least one power-consuming member.

3. The plasma processing apparatus of claim 2, wherein the controller has a table in which a peak value and a duty ratio of the output voltage and an amplitude of the output current corresponding to the parameter value are stored in association with the parameter value, and is configured to cause the power transmitting unit to output the output power having a peak value and a duty ratio of the output voltage and an amplitude value of the output current corresponding to the parameter value.

4. The plasma processing apparatus of claim 2, further comprising:
a line capacitor;
an excess power-consuming load; and
a switching element configured to selectively connect the line capacitor between a pair of power supply lines that connect the rectifying and smoothing unit and the constant voltage controller to each other or to selectively connect the line capacitor to the excess power-consuming load.

5. The plasma processing apparatus of claim 4, wherein the constant voltage controller includes a controller configured to change a load resistance value of said at least one power-consuming member, and to control the switching element.

6. The plasma processing apparatus of claim 5, wherein the controller of the constant voltage controller is configured to control the switching element to connect the line capacitor to the pair of power supply lines when the load resistance value of said at least one power-consuming component changes to be decreased, and then control the switching element to connect the line capacitor to the excess power-consuming load in order to discharge the power stored in the line capacitor to the excess power-consuming load.

7. The plasma processing apparatus of claim 2, further comprising:
an immittance converter including an immittance conversion circuit connected between the power transmitting unit and the power transmitting coil.

8. The plasma processing apparatus of claim 7, wherein the immittance conversion circuit includes:
an inductor connected between the power transmitting unit and the power transmitting coil; and
a capacitor connected between a pair of power supply lines that connect the power transmitting unit and the power transmitting coil to each other.

9. The plasma processing apparatus of claim 8, wherein the power transmitting unit includes:
a rectifying and smoothing unit including a rectifying circuit and a smoothing capacitor connected between the power transmitting coil and the rectifying circuit;
an inverter connected between the power transmitting coil and the rectifying and smoothing unit of the power transmitting unit;
a voltage monitoring part configured to monitor a waveform of a voltage outputted from the rectifying and smoothing unit of the power transmitting unit; and
and a controller,
wherein the controller is configured to adjust a duty ratio of the output voltage outputted from the inverter in accordance with the waveform monitored by the voltage monitoring part to suppress ripples of the output power.

10. The plasma processing apparatus of claim 8, further comprising:
an AC/DC converter,
wherein the power transmitting unit includes:
a smoothing unit including a smoothing capacitor and connected to the AC/DC converter,
an inverter connected between the power transmitting coil and the smoothing unit of the power transmitting unit,
a voltage monitoring part configured to monitor a waveform of a voltage outputted from the smoothing unit of the power transmitting unit, and
a controller,
wherein the controller is configured to adjust the duty ratio of the output voltage outputted from the inverter in accordance with the waveform monitored by the voltage monitoring part to suppress ripples of the output power.

11. The plasma processing apparatus of claim 7, further comprising:
a resonant capacitor connected between the power transmitting coil and the immittance conversion circuit,
wherein the resonant capacitor is provided in the immittance converter.

12. The plasma processing apparatus of claim 7, wherein the immittance converter and the power transmitting unit are accommodated in a single housing.

13. The plasma processing apparatus of claim 7, further comprising:
a resonant capacitor connected between the power transmitting coil and the immittance conversion circuit,
wherein the resonant capacitor, the immittance converter, and the power transmitting unit are accommodated in a single housing.

14. The plasma processing apparatus of claim 7, further comprising:
a power transmitting coil unit including the power transmitting coil and a resonant capacitor connected between the power transmitting coil and the immittance conversion circuit,
wherein the power transmitting coil unit and the immittance converter are accommodated in a single housing.

15. The plasma processing apparatus of claim 7, further comprising:
a power transmitting coil unit including the power transmitting coil and a resonant capacitor connected between the power transmitting coil and the immittance conversion circuit,
wherein the power transmitting coil unit, the immittance converter, and the power transmitting unit are accommodated in a single housing.

16. The plasma processing apparatus of claim 10, further comprising:
a resonant capacitor connected between the power transmitting coil and the immittance conversion circuit,
wherein the resonant capacitor, the AC/DC converter, the immittance converter, and the power transmitting unit are accommodated in a single housing.

17. The plasma processing apparatus of claim 10, further comprising:
a power transmitting coil unit including the power transmitting coil and a resonant capacitor connected between the power transmitting coil and the immittance conversion circuit,
wherein the power transmitting coil unit, the AC/DC converter, the immittance converter, and the power transmitting unit are housed in a single housing.
